(19) United States
(12) Patent Application Publication
(10) Pub. No.: US 2011/0031482 A1
(43) Pub. Date: Feb. 10, 2011

(54) ORGANIC ELECTROLUMINESCENT ELEMENT AND METHOD OF MANUFACTURING THE SAME

(75) Inventors: Shun FURUKAWA, Tokyo (JP); Yoshiyuki SUZURI, Tokyo (JP); Mitsuyoshi NAITO, Osaka (JP)

Correspondence Address: CANTOR COLBURN LLP, 20 Church Street, 22nd Floor, Hartford, CT, 06103, US

(73) Assignee: KONICA MINOLTA HOLDINGS, INC., Tokyo (JP)

(21) Appl. No.: 12/848,501

(22) Filed: Aug. 2, 2010

(30) Foreign Application Priority Data
Aug. 5, 2009 (JP) 2009-182221
May 13, 2010 (JP) 2010-110866

(51) Int. Cl. H01L 51/54; H01L 51/56

(52) U.S. Cl. 257/40; 438/46; 257/E51.027

(57) ABSTRACT

An organic electroluminescent element comprising: an organic laminate comprising at least an light emission layer formed via a wet process, the light emission layer comprising a host material and a guest material; and a pair of electrodes, wherein a solvent used for forming the light emission layer has a boiling point of 105° C. or less and a saturation vapor pressure at 20° C. of 20 mmHg or more, and a method of manufacturing the organic electroluminescent element

This application is based on Japanese Patent Application No. 2009-182221 filed on Aug. 5, 2009, and No. 2010-110866 filed on May 13, 2010 in Japanese Patent Office, the entire content of which is hereby incorporated by reference.

### TECHNICAL FIELD

The present invention relates to an organic electroluminescent element and a method of manufacturing the same, and, in more detail, relates to an organic electroluminescent element driven by a low voltage, and exhibiting a high efficiency and a low elevation in driving voltage under continuous operation.

### BACKGROUND

Electroluminescent displays are known as light emitting type electronic display device (hereafter, referred to as ELD). An inorganic electroluminescent element (hereafter, referred to as inorganic EL element) and an organic electroluminescent element (hereafter, referred to as organic EL element) are cited as examples of the ELD. The inorganic EL element has been used as a planar light source, in which a high alternating voltage is required for driving the light emitting device.

The organic EL element is an element having a light emission layer containing a light emitting compound placed between a cathode and an anode, in which electrons and positive holes are injected into the light emission layer and excitons are generated by recombination of them, and fluorescent light or phosphorescent light is emitted on the occasion of quenching of the excitons. Such the device is noted because which can emit light by application of a voltage of several to several tens volts, and has wide viewing angle and high visibility since it is a self light emission type, and is completely solid state thin device suitable for space saving and portable appliance.

An organic electroluminescent element has a characteristic feature that it is a surface light source unlike the conventional light sources which have been mainly used, for example, a light-emitting diode and a cold cathode tube. As an application which can effectively utilize this characteristic, there are cited a light source for illumination and a back light of various displays. Specifically, an organic electroluminescent element may be preferably used as a back light of a full color liquid crystal display the demand of which has been remarkably increased in these years.

As a problem to practically utilize an organic electroluminescent element as a light source for illumination and a back light of various displays, improvement in luminous efficiency may be important. In order to improve the luminous efficiency, it is becoming common to use so called a host-guest type constitution in a portion of an organic functional layer constituting an organic electroluminescent element, in which a plurality of materials having different functions are combined.

An organic electroluminescent element can be manufactured, for example, by a vacuum evaporation method or via a wet process (such as a spin coat method, a casting method, an inkjet method, a spray method, slit die coat method or a printing method) which is also called as a coating method. Of these, a manufacturing method employing a wet process is attracting attention in recent years, because no vacuum process is needed, whereby a continuous production can be easily conducted.

However, an organic EL element manufactured via a wet process does not show a sufficient property as an element when compared with an element manufactured by a vacuum evaporation method. Specifically, the driving voltage and elevation in the driving voltage while continuous operation tend to increase. This may be because, in the organic EL element manufactured via a wet process, migration of carriers tends to be disturbed because of the different condition of the layers from those of an organic EL element manufactured via a dry process, caused by the mixing of neighboring layers or morphology change of the layers, or because the residual solvent in the layer may work as a carrier trap which disturbs the migration of carriers while the element is driven, whereby increase of driving voltage tends to occur.

When the carrier is trapped, the inside of the layer may be in the state of too much carrier to deteriorate the element, which further increase the carrier trap, and deterioration of the element may be promoted, and the elevation in the driving voltage while continuous operation may further be accelerated.

As a method to improve the property an organic EL element manufactured via a wet process, proposed has been a method of forming a light emission layer in which the solvent to dissolve the light emission material is contrived. For example, a method to prepare a precursor of a polyparaphenylene vinylene light emission material is by using a hydrophilic high boiling point solvent has been disclosed in Japanese Patent Application Publication (hereafter referred to as JP-A) No. 11-339957.

A method to form a light emission layer using a screen printing method in which the vapor pressure at 25° C. and the boiling point of the solvent used in the method are prescribed has been disclosed, for example, in JP-A No. 2002-170674, and, further, a method to use two or more kinds of solvents for forming a light emission layer, in which the solvents are contrived to use at least one solvent having a boiling point of less than 100° C. has been disclosed in JP-A No. 2004-31077. However, in these patent documents, a high boiling point solvent and a low vapor pressure solvent have been used, and no example of using a low boiling point solvent and a high vapor pressure solvent has not been disclosed.

Further, a method to form a light emission layer by using a low boiling point solvent under a low temperature atmosphere has been disclosed, for example, in JP-A No. 2007-220426. However, the concept of the present invention which will be explained later has not been disclosed.

### SUMMARY

In view of foregoing problems, as the results of an intensive study in the present invention, it was found that the property of an organic EL element can be improved not only by suppressing the boiling point of a solvent used in the formation of a light emission layer, but also by elevating the vapor pressure at an ambient temperature of a solvent.

An object of the present invention is to provide an organic electroluminescent element exhibiting a high luminance efficiency and a low driving voltage while the elevation in driving voltage under continuous operation is suppressed, the light emission layer of the organic electroluminescent element containing a host material and a guest material and being manufactured via a wet process, as well as to provide a method of manufacturing the organic electroluminescent element.

One of the aspects of the present invention is an organic electroluminescent element comprising: an organic laminate comprising at least an light emission layer formed via a wet process, the light emission layer comprising a host material and a guest material; and a pair of electrodes, wherein a solvent used for forming the light emission layer has a boiling point of 105° C. or less and a saturation vapor pressure at 20° C. of 20 mmHg or more.

Another aspect of the present invention is a method of manufacturing an organic electroluminescent element comprising, (I) the steps of: forming an anode on a substrate; forming an organic laminate on the anode; and forming a cathode on the organic laminate, or (II) the steps of: forming a cathode on a substrate; forming an organic laminate on the cathode; and forming an anode on the organic laminate, wherein the step of forming the organic laminate comprises at least a step of forming a light emission layer via a wet process, the light emission layer comprising a host material and a guest material; wherein a solvent used for forming the light emission layer has a boiling point of 105° C. or less and a saturation vapor pressure at 20° C. of 20 mmHg or more.

### DESCRIPTION OF THE PREFERRED EMBODIMENT

The above object of the present invention is achieved by the following structures.

(1) An organic electroluminescent element comprising:

an organic laminate comprising at least an light emission layer formed via a wet process, the light emission layer comprising a host material and a guest material; and

a pair of electrodes,

wherein a solvent used for forming the light emission layer has a boiling point of 105° C. or less and a saturation vapor pressure at 20° C. of 20 mmHg or more.

(2) The organic electroluminescent element of Item (1), wherein the solvent has a boiling point of 75° C. or more and a saturation vapor pressure at 20° C. of 70 mmHg or less.

(3) The organic electroluminescent element of Item (1) or (2), wherein

the organic laminate further contains three or more layers selected from the group consisting of a hole injection layer, a hole transport layer, a hole blocking layer, an electron injection layer, an electron transport layer and an electron blocking layer, and

the three or more layers each are formed via a wet process.

(4) The organic electroluminescent element of any one of Items (1) to (3), wherein the solvent contains a carbonyl group.

(5) The organic electroluminescent element of any one of Items (1) to (3), wherein the solvent contains an ester group.

(6) The organic electroluminescent element of any one of Items (1) to (3), wherein the solvent is selected from the group consisting of normal propyl acetate, isopropyl acetate and methyl propionate.

(7) The organic electroluminescent element of any one of Items (1) to (6), wherein a molecular weight of the host material is 1500 or less.

(8) The organic electroluminescent element of any one of Items (1) to (6), wherein the host material is represented by following Formula (a):

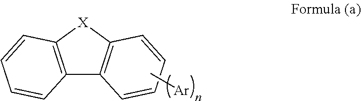

wherein X represents NR′, O, S, CR′R″ or SiR′R″, R′ and R″ each represent a hydrogen atom or a substituent, Ar represents a group of atoms necessary to form an aromatic ring, and n represents an integer of 0-8.

(9) The organic electroluminescent element of Item (8), wherein Ar in Formula (a) is selected from the group consisting of a carbazole ring, a carboline ring, a dibenzofuran ring and a benzene ring.

(10) The organic electroluminescent element of any one of Items (1) to (9), wherein the light emission layer contains at least three different light emission dopants.

(11) A method of manufacturing an organic electroluminescent element comprising,
(I) the steps of:
   forming an anode on a substrate;
   forming an organic laminate on the anode; and
   forming a cathode on the organic laminate, or
(II) the steps of
   forming a cathode on a substrate;
   forming an organic laminate on the cathode; and
   forming an anode on the organic laminate,
      wherein the step of forming the organic laminate contains at least a step of forming a light emission layer via a wet process, the light emission layer comprising a host material and a guest material;

wherein a solvent used for forming the light emission layer has a boiling point of 105° C. or less and a saturation vapor pressure at 20° C. of 20 mmHg or more.

(12) The method of Item (11), wherein the solvent has a boiling point of 75° C. or more and a saturation vapor pressure at 20° C. of 70 mmHg or less.

(13) The method of Item (11) or (12), wherein

the organic laminate further contains three or more layers selected from the group consisting of a hole injection layer, a hole transport layer, a hole blocking layer, an electron injection layer, an electron transport layer and an electron blocking layer, and the three or more layers each are formed via a wet process.

(14) The method of any one of Items (11) to (13), wherein the solvent contains a carbonyl group.

(15) The method of any one of Items (11) to (13), wherein the solvent contains an ester group.

(16) The method of any one of Items (11) to (13), wherein the solvent is selected from the group consisting of normal propyl acetate, isopropyl acetate and methyl propionate.

(17) The method of any one of Items (11) to (16), wherein a molecular weight of the host material is 1500 or less.

(18) The method of any one of Items (11) to (16), wherein the host material is represented by following Formula (a):

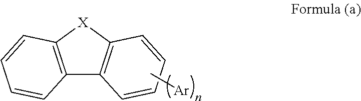

wherein X represents NR′, O, S, CR′R″ or SiR′R″, R′ and R″ each represent a hydrogen atom or a substituent, Ar represents a group of atoms necessary to form an aromatic ring, and n represents an integer of 0-8.

(19) The method ahem (18), wherein Ar in Formula (a) is selected from the group consisting of a carbazole ring, a carboline ring, a dibenzofuran ring and a benzene ring.

(20) The method of any one of Items (11) to (19), wherein the light emission layer contains at least three different light emission dopants.

According to the present invention, an organic electroluminescent element exhibiting a high luminance efficiency and a low driving voltage while the elevation in driving voltage under continuous operation is suppressed, the light emission layer of the organic electroluminescent element containing a host material and a guest material and being manufactured via a wet process, and a method of manufacturing the organic electroluminescent element can be provided.

Each component of the organic EL element of the present invention will be explained in detail below, however, the present invention is not limited thereto.

In the present invention, the organic EL element having a light emission layer containing a host material and a guest material (hereafter, also referred to as a host-guest type light emission layer) is characterized in that at least a light emission layer is formed via a wet process and the solvent used for forming the light emission layer has a boiling point of 105° C. or less and a saturation vapor pressure at 20° C. of 20 mmHg or more. Having a boiling point of 105° C. or less means specifically that the boiling point of the solvent used for dissolving the emission dopant is 105° C. or less.

The reason why the luminance efficiency and the driving voltage are improved by manufacturing an organic EL element in this manner is not fully clear, however, it is expected that the dissolution or mixing of the lower layer can be suppressed by reducing the duration of boundary layer limiting. It is also expected that the morphology of the layer s became closer to that of layers formed via a dry process.

Further, by adjusting the molecular weight of the host material in the host-guest type light emission layer to be 1500 or less and fixing the structure of the host material as represented by Formula (a), a condition of swelling which is often observed when a polymer material is used can be suppressed. Namely, the removal of the solvent has become easier by preventing holding of the solvent in the layer.

As the result, the property of an organic EL element which is closer to the property of an organic EL element manufactured via a dry process has been achieved, since the morphology of the obtained layers has become closer to that of layers formed via a dry process. Any kind of solvent is applicable as far as the boiling point is 105° C. or less and the saturation vapor pressure at 20° C. is 20 mmHg or more.

Examples of a solvent used for forming a light emission layer include: chloroform, carbon tetrachloride, 1,1-dichloroethane, 1,2-dichloroethane, acetonitrile, propionitrile, benzene, ethylacetate, normal propyl acetate, isopropyl acetate, methyl propionate, acetone, methyl ethyl ketone, tetrahydrofuran and triethylamine. In view of the stability of the surface after forming the layer, the solvent more preferably has a saturation vapor pressure at 20° C. of 70 mmHg or less and a boiling point of 75° C. or more. Examples of such a solvent include: 1,2-dichloroethane, propionitrile, normal propyl acetate, methyl propionate, and triethylamine.

With respect to the structure of the solvent, a solvent having a carbonyl group is preferable, and a solvent having an ester group is further preferable. Specific examples of such a solvent include: ethylacetate, normal propyl acetate, isopropyl acetate, methyl propionate, acetone and methyl ethyl ketone, and more preferably, ethylacetate, normal propyl acetate, isopropyl acetate and methyl propionate.

The purity of a solvent is preferably as high as possible, since one of the major differences between the layer formed via a wet process and the layer formed via a dry process is that the layer formed via a wet process is possibly contaminated with an impurity of solvent origin. Specifically, the purity of the solvent is preferably 99.5% or more and more preferably 99.8% or more.

### <<Layer Arrangement of Organic EL Element>>

Preferable concrete examples of the layer constitution of the organic EL element of the present invention are listed below, however, the present invention is not limited thereto.

(i) Anode/Light emission layer/Electron transport layer/Cathode

(ii) Anode/Positive hole transport layer/Light emission layer/Electron transport layer/Cathode

(iii) Anode/Positive hole transport layer/Light emission layer/Positive hole blocking layer/Electron transport layer/Cathode

(iv) Anode/Positive hole transport layer/Light emission layer/Positive hole blocking layer/Electron transport layer/Cathode buffer layer/Cathode

(v) Anode/Anode buffer layer/Positive hole transport layer/Light emission layer/Positive hole blocking layer/Electron transport layer/Cathode buffer layer/Cathode

Among the above described layers, the layers other than the anode and the cathode are also generically called as an organic laminate. Hereafter, a positive hole is also referred to merely as a hole.

Each layer will be explained below.

### <<Light Emission Layer>>

The light emission layer is a layer in which electrons and positive holes each injected from the electrodes or from such as the electron transport layer and the positive hole transport layer are recombined to emit light and the portion of light emission may be inside of the layer or the interface of the light emission layer and the adjacent layer, however, the portion of light emission is preferably inside of the layer because the exciton is possibly inactivated at the interface.

The thickness of the light emission layer is not specifically limited but preferably adjusted within the range of from 2 nm to 200 nm and more preferably from 5 nm to 100 nm, in view of uniformity of the layer, prevention of applying unnecessary high voltage at the occasion of light emission and improving stability of emission color against driving current,

In the present invention, by selecting the boiling point and the vapor pressure at 20° C. of the solvent, the functional group of the solvent and the molecular weight of the light emission host in the occasion of forming a host-guest type light emission layer via a wet process, not only the external quantum efficiency and the driving voltage of the obtained element is improved, but also the elevation in driving voltage under continuous operation is suppressed.

The host compound (also referred to as the light emission host) and the light emission dopant used in the light emission layer will be explained below.

### <<Host Compound>>

The host compound used in the present invention will be described.

In the present invention, the host compound means a compound having a mass content of 20% or more in the compounds contained in the light emission layer, and exhibiting a phosphorescent quantum efficiency of the phosphorescent light emission of less than 0.1 and more preferably less than 0.01 at room temperature (25° C.).

As the host compound, known host compounds may be used alone or in combination of plural kinds thereof. The transport of charge can be controlled by the combination use of the host compounds so as to raise the efficiency of the organic EL element. Moreover, mixing of different emitted light is made possible by the use of plural kinds of light emission dopants, whereby optional color light can be obtained.

In the present invention, a compound represented by Formula (a) is preferably employed as a host compound.

In Formula (a), examples of a substituent represented by each of R′ and R″ in X include: an alkyl group (for example, a methyl group, an ethyl group, a propyl group, an isopropyl group, a tert-butyl group, a pentyl group, a hexyl group, an octyl group, a dodecyl group, a tridecyl group, a tetradecyl group, or a pentadecyl group); a cycloalkyl group (for example, a cyclopentyl group or a cyclohexyl group); an alkenyl group (for example, a vinyl group or an allyl group); an alkynyl group (for example, an ethynyl group or a propargyl group); an aromatic hydrocarbon group (also referred to as an aromatic carbon ring group or an aryl group, for example, a phenyl group, a p-chlorophenyl group, a mesityl group, a tolyl group, a xylyl group, a naphthyl group, an anthryl group, an azulenyl group, an acenaphthenyl group, a fluorenyl group, a phenanthryl group, an indenyl group, a pyrenyl group, or a biphenylyl group); an aromatic heterocyclyl group (for example, a pyridyl group, a pyrimidinyl group, a furyl group, a pyrrolyl group, an imidazolyl group, a benzoimidazolyl group, a pyrazolyl group, a pyrazinyl group, a triazolyl group (for example, an 1,2,4-trazole-1-yl group or an 1,2,3-trazole-1-yl group), an oxazolyl group, a benzoxazolyl group, a thiazolyl group, an isoxazolyl group, an isothiazolyl group, a furazanyl group, a thienyl group, a quinolyl group, a benzofuryl group, a dibenzofuryl group, a benzothienyl group, a dibenzothienyl group, an indolyl group, a carbazolyl group, a carbolinyl group, a diazacarbazolyl group (referring to the group in which any one of carbon atoms constituting the carboline ring of the aforesaid carbolinyl group is replaced with a nitrogen atom), a quinoxalinyl group, a pyridazinyl group, a triazinyl group, a quinazolynyl group, or a phthalazinyl group; a heterocyclyl group (for example, a pyrrolidyl group, an imidazolyl group, a morpholyl group, and an oxazolidyl group); an alkoxy group (for example, a methoxy group, an ethoxy group, a propyloxy group, a pentyloxy group, a hexyloxy group, an octyloxy group, and a dodecyloxy group); a cycloalkoxy group (for example, a cyclopentyloxy group and a cyclohexyloxy group); and aryloxy group (for example, a phenoxy group and naphthyloxy group); and alkylthio group (for example, a methylthio group, an ethylthio group, a propylthio group, a pentylthio group, a hexylthio group, an octylthio group, and a dodecylthio group); an cycloalkylthio group (for example, a cyclopentylthio group and a cyclohexylthio group); and arylthio group (for example, a phenylthio group and a naphthylthio group); an alkoxycarbonyl group (for example, a methyloxycarbonyl group, an ethyloxycarbonyl group, a butyloxycarbonyl group, an octyloxycarbonyl group, and a dodecyloxycarbonyl group); an aryloxycarbonyl group (for example, a phenyloxycarbonyl group, a naphthyloxycarbonyl group); a sulfamoyl group (for example, an aminosulfonyl group, a methylaminosulfonyl group, a dimethylaminosulfonyl group, a butylaminosulfonyl group, a hexylaminosulfonyl group, a cyclohexylaminosulfonyl group, an octylaminosulfonyl group, a dodecylaminosulfonyl group, a phenylaminosulfonyl group, a naphthylaminosulfonyl group, and a 2-pyridylaminosulfonyl group); an acyl group (for example, an acetyl group, an ethylcarbonyl group, a propylcarbonyl group, a pentylcarbonyl group, a cyclohexylcarbonyl group, an octylcarbonyl group, a 2-ethylhexylcarbonyl group, a dodecylcarbonyl group, a phenylcarbonyl group, a naphthylcarbonyl group, and a pyridylcarbonyl group); and acyloxy group (for example, an acetyloxy group, an ethylcarbonyloxy group, a butylcarbonlyloxy group, an octylcarbonyloxy group, a dodecylcarbonyloxy group, and a phenylcarbonyloxy group); an amido group (for example, a methylcarbonylamino group, an ethylcarbonylamino group, a dimethylcarbonylamino group, a propylcarbonylamino group, a pentylcarbonylamino group, a cyclohexylcarbonylamino group, a 2-ethylcarbonylamino group, an octylcarbonylamino group, a dodecylcarbonylamino group, a phenylcarbonylamino group, and a naphthylcarbonlylamino group); a carbamoyl group (for example, an aminocarbonyl group, a methylaminocarbonyl group, a dimethylaminocarbonyl group, a propylaminocarbonyl group, a pentylaminocarbonyl group, a cyclohexylaminocarbonyl group, an octylaminocarbonyl group, a 2-ethylhexylaminocarbonyl group, a dodecylaminocarbonyl group, a phenylaminocarbonyl group, a naphthylaminocarbonyl group, and a 2-pyridylaminocarbonyl group); a ureido group (for example, a methylureido group, an ethylureido group, a pentylureido group, a cyclohexylureido group, an octylureido group, a dodecylureido group, a phenylureido group, a naphthylureido group, and a 2-pyridylaminoureido group); a sulfinyl group (for example, a methylsulfinyl group, an ethylsulfinyl group, a butylsulfinyl group, a cyclohexylsulfinyl group, a 2-ethylhexylsulfinyl group, a dodecylsulfinyl group, a phenylsulfinyl group, a naphthylsulfinyl group, and a 2-pyridylsulfinyl group); an alkylsulfonyl group (for example, a methylsulfonyl group, an ethylsulfonyl group, a butylsulfonyl group, a cyclohexylsulfonyl group, a 2-ethylhexylsulfonyl group, and a dodecylsulfonyl group); an arylsulfonyl or heteroarylsulfonyl group (for example, a phenylsulfonyl group, a naphthylsulfonyl group, and a 2-pyridylsulfonyl group); an amino group (for example, an amino group, an ethylamino group, a dimethylamino group, a butylamino group, a cyclopentylamino group, a 2-ethylhexylamino group, a dodecylamino group, an anilino group, a naphthylamino group, and a 2-pyridylamino group); a halogen atom (for example, a fluorine atom, a chlorine atom, and a bromine atom); a fluorinated hydrocarbon group (for example, a fluoromethyl group, a trifluoromethyl group, a pentafluoroethyl group, and a pentafluorophenyl group); a cyano group, a nitro group, a hydroxyl group, a mercapto group; a silyl group (for example, a trimethylsilyl group, a triisopropylsilyl group, a triphenylsilyl group, and a phenyldiethylsilyl group); and a phosphono group. These substituents may be further substituted with the aforesaid substituents. Further, a plurality of these substituents may be combined with each other to form a ring.

Preferable as X in Formula (a) is NR′ or O, and examples of a specifically preferable compound for R′ include: an aromatic hydrocarbon group (also referred to as an aromatic carbon ring group or an aryl group, for example, a phenyl group, a p-chlorophenyl group, a mesityl group, a tolyl group, a xylyl group, a naphthyl group, an anthryl group, an azulenyl group, an acenaphthenyl group, a fluorenyl group, a phenanthryl group, an indenyl group, a pyrenyl group and a biphenylyl group); and an aromatic heterocyclyl group (for example, a furyl group, a thienyl group, a pyridyl group, a pyridazinyl group, a pyrimidinyl group, a pyrazinyl group, a triazinyl group, an imidazolyl group, a pyrazolyl group, a thiazolyl group, a quinazolinyl group and a phthalazinyl group).

Aforementioned aromatic hydrocarbon groups and aromatic heterocyclyl groups may further be substituted with a group represented by R′ or R″ of X in Formula (a).

Examples of the aromatic group represented by Ar include an aromatic hydrocarbon group and an aromatic heterocyclic group. The aromatic ring may be a single ring or condensed ring, and may have no substituent or a substituent mentioned later.

Examples of the aromatic hydrocarbon ring represented by Ar in Formula (a) include a benzene ring, a biphenyl ring, a naphthalene ring, an azulene ring, an anthracene ring, a phenanthrene ring, a pyrene ring, a chrysene ring, a naphthacene ring, a triphenylene ling an o-terphenyl ring, an m-terphenyl ring, a p-terphenyl ring, an acenaphthene ring, a coronene ring, a fluorene ring, a fluoranthrene ring, a naphthacene ring, a pentacene ring, a perylene ring, a pentaphene ring, a picene ring, a pyrene ring, a pyranthrene ring and an anthranthrene ring. These rings may further have a substituent represented by R′ or R″ of X in the substructure represented by Formula (a).

In the substructure represented by Formula (a), examples of an aromatic heterocycle represented by Ar include: a furan ring, a dibenzofuran ring, a thiophene ring an oxazole ring, a pyrrole ring, a pyridine ring a pyridazine ring, a pyrimidine ring, a pyrazine ring, a triazine ring, a benzimidazole ring, an oxadiazole ring, a triazole ring, an imidazole ring, a pyrazole ring, a thiazole ring, an indole ring, an indazole ring, a benzoimidazole ring, a benzothiazole ring, a benzoxazole ring, a quinoxaline ring, a quinazoline ring a cinnoline ring, a quinoline ring, an isoquinoline ring, a phthalazine ring, a naphthyridine ring, a carbazole ring, a carboline ring and a diazacarbazole ring (indicating a group in which one of the carbon atoms constituting the carboline ring is replaced with a nitrogen atom).

These rings may further have a substituent represented by R′ or R″ of X in the substructure represented by Formula (a).

Among these rings, preferably used as an aromatic ring represented by Ar in Formula (a) are: a carbazole ring, a carboline ring, a dibenzofuran ring and benzene ring, more preferably, a carbazole ring, a carboline ring and benzene ring, further more preferably, a benzene ring having a substituent, and specifically preferably, a benzene ring having a carbazolyl group.

In one of a preferable embodiment an aromatic ring represented by Ar in the Formula (a), are condensed rings with three or more rings, and specific examples of a condensed aromatic hydrocarbon ring having three or more rings include: a naphthacene ring, an anthracene ring, a tetracene ring, a pentacene ring, a hexacene ring, a phenanthrene ring, a pyrene ring, a benzopyrene ring, a benzazulene ring, a chrysene ring, a benzochrysene ring, an acenaphthene ring, an acenaphthylene ring, a triphenylene ring, a coronene ring, a benzocoronene ring, a hexabenzocorone ring, a fluorene ring, a benzofluorene ring a fluoranthene ring, a perylene ring, a naphthoperylene ring, a pentabenzoperylene ring, a benzoperylene ring, a pentaphene ring, a picene ring, a pyranthrene ring, a coronene ring, a naphthocoronene ring, an ovalene ring and an anthraanthrene ring. In addition, these rings may further have an above substituent.

Moreover, examples of a condensed aromatic heterocycle having three or more rings include: an acridine ring, a benzoquinoline ring, a carbazole ring, a carboline ring, a phenazine ring, a phenanthridine ring, a phenanthroline ring, a carboline ring, a cycladine ring, a quindoline ring, a thebenidine ring, a quinindoline ring, a triphenodithiazine ring, a triphenodioxazine ring, a phenanthrazine ring, an anthrazine ring, a perimizine ring a diazacarbazole ring (indicating a ring structure in which one of the carbon atoms constituting the carboline ring is replaced with a nitrogen atom), a phenanthroline ring, a dibenzofuran ring, a dibenzothiophene ring, a naphthofuran ring, a naphthothiophene ring, a benzodifuran ring, a benzodithiophene ring, a naphthodifuran ring, a naphthodithiophene ring, an anthrafuran ring, an anthradifuran ring, an anthrathiophene ring, an anthradithiophene ring, a thianthrene ring, a phenoxthine ring, and a thiophanthrene ring (naphthothiophene ring). These rings may further have a substituent.

In Formula (a), n represents an integer of 0 to 8, more preferably an integer of 0 to 2. Specifically, when X is O or S, it is preferable that n is 1 or 2.

Specific examples of a host compound represented by Formula (a) will be shown below, however, the present invention is not limited thereto.

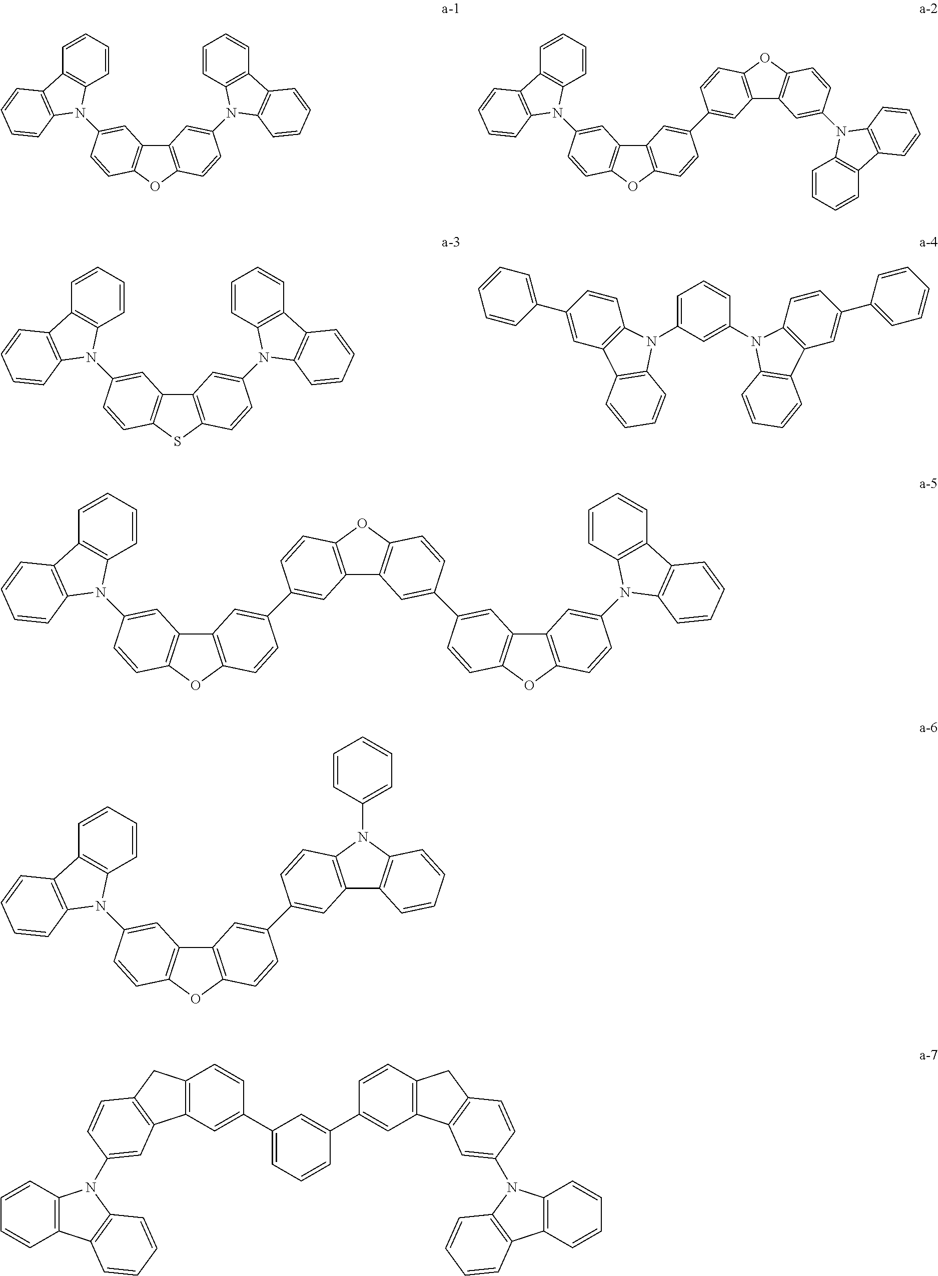

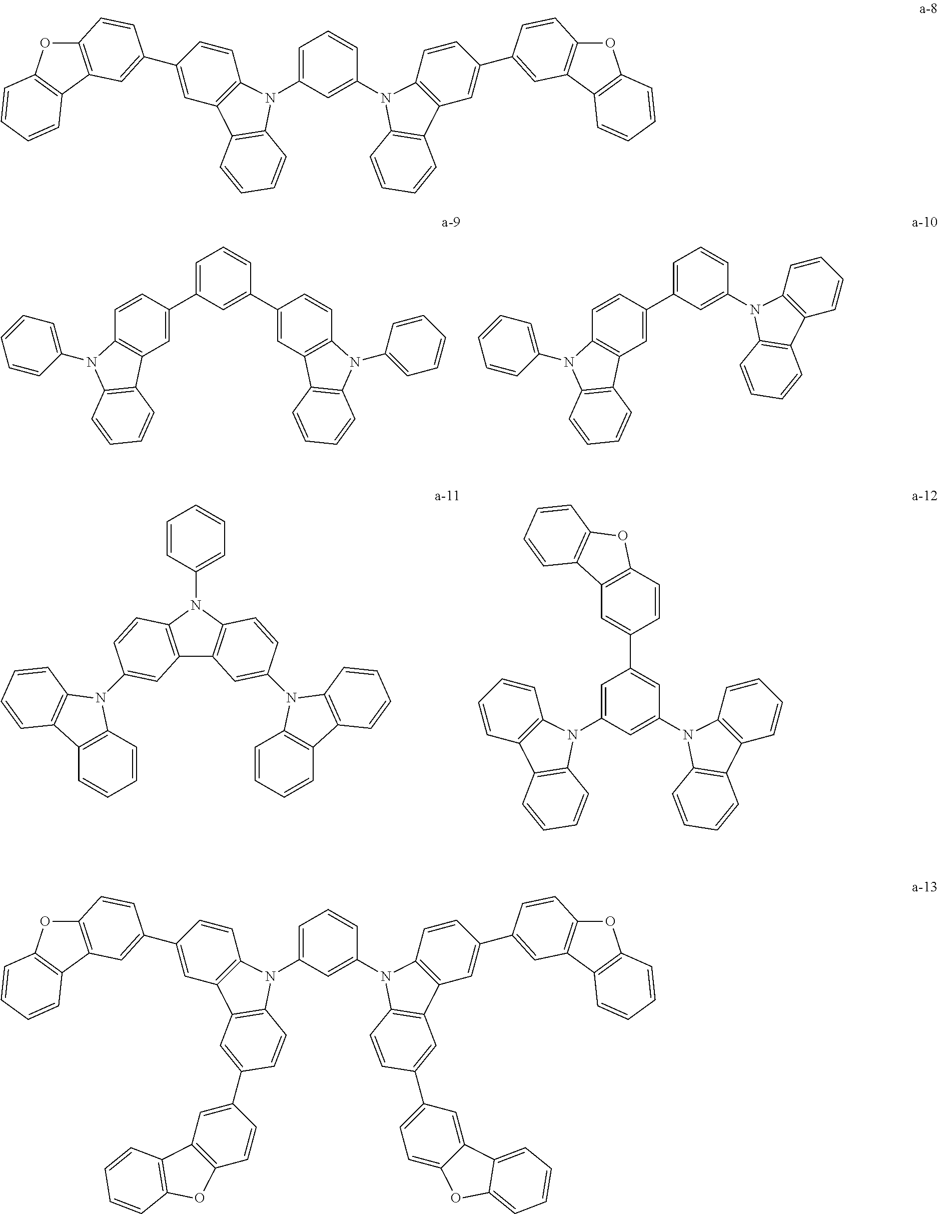

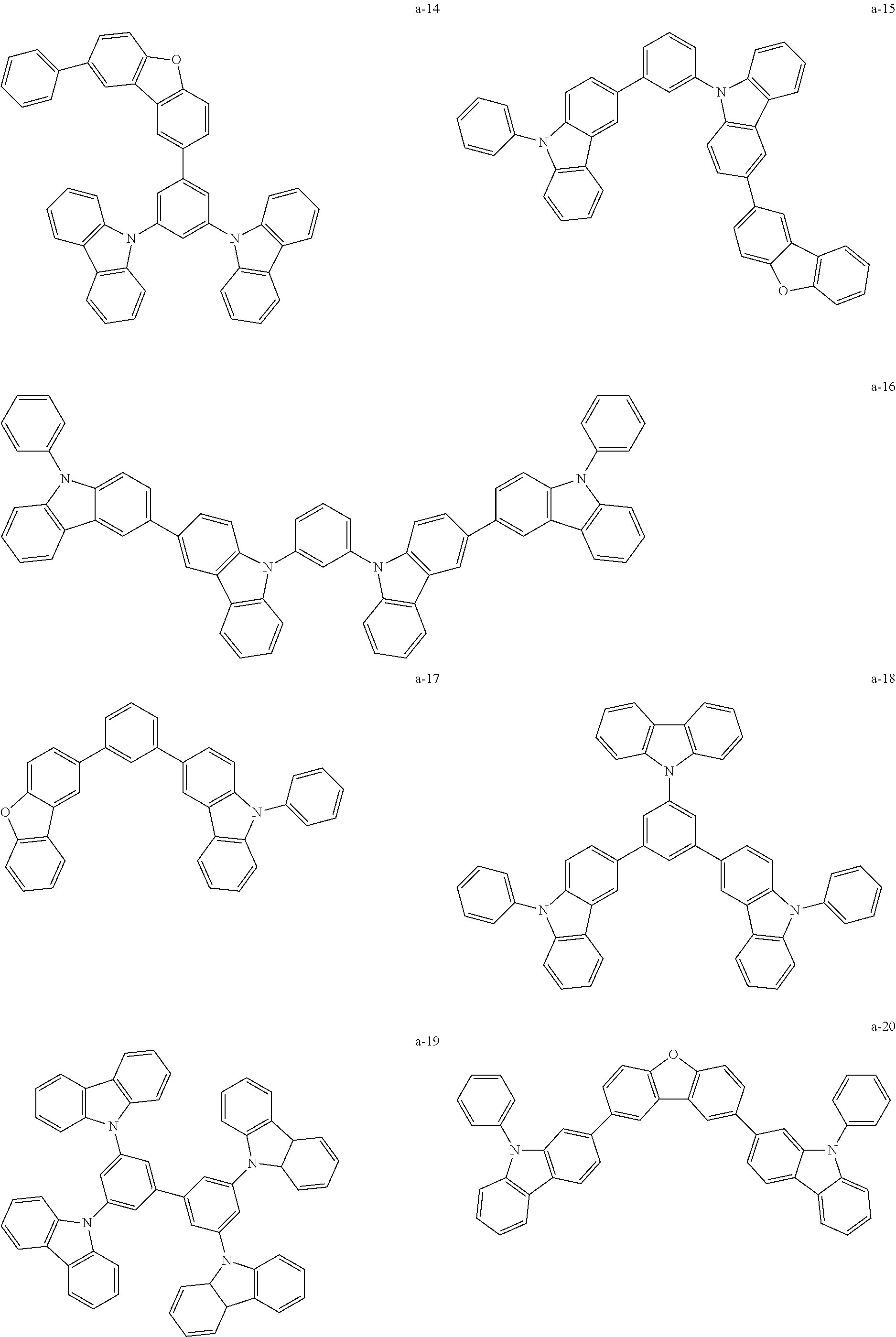

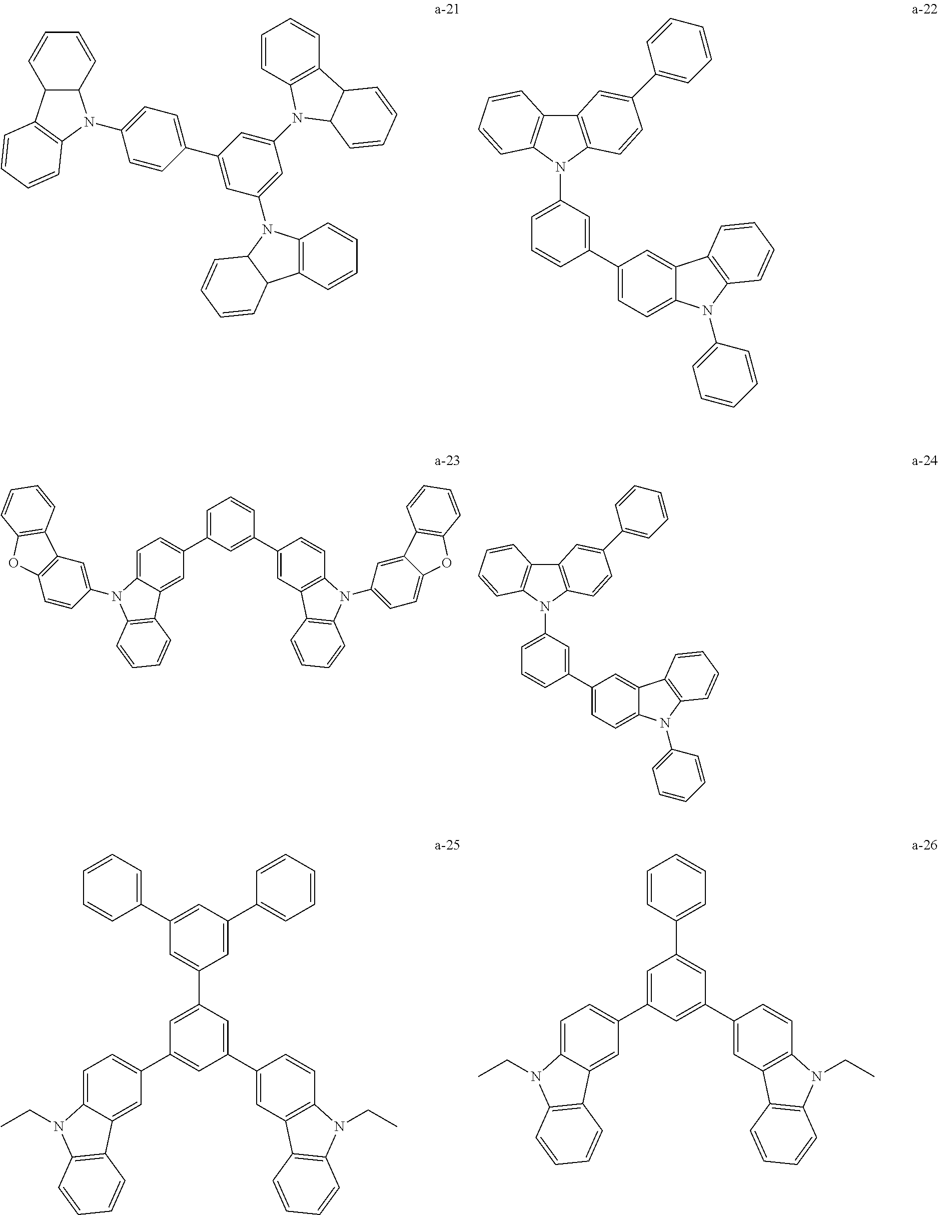

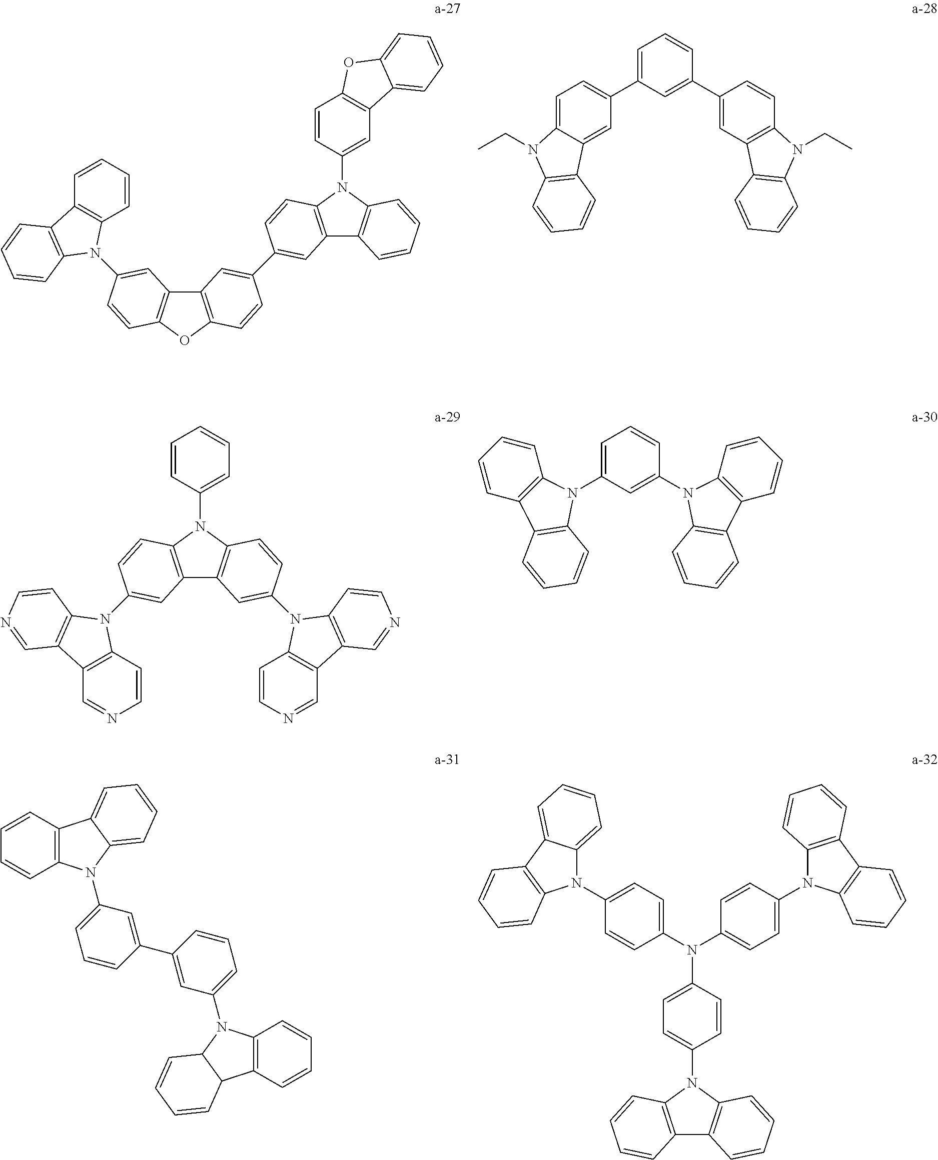

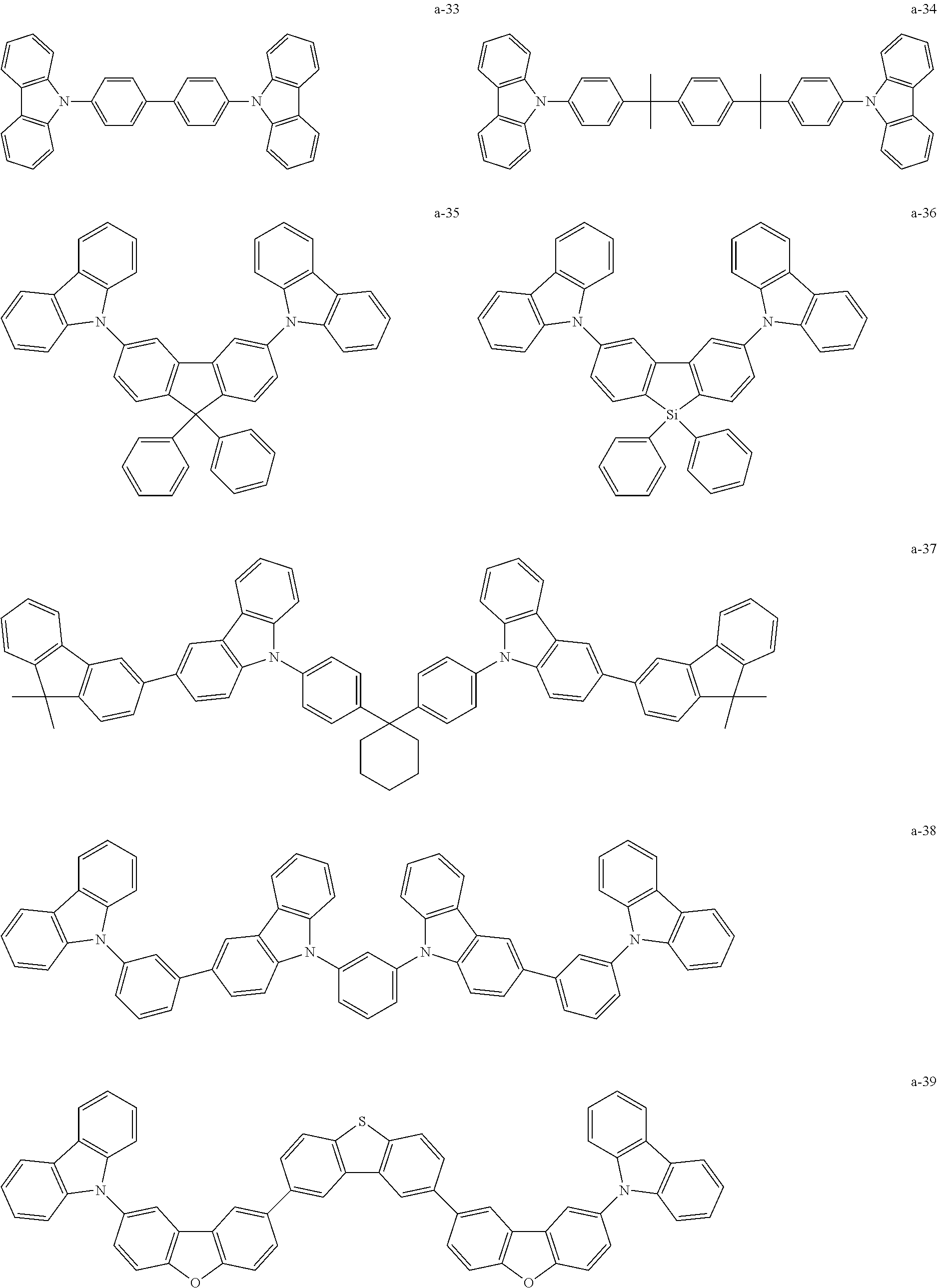

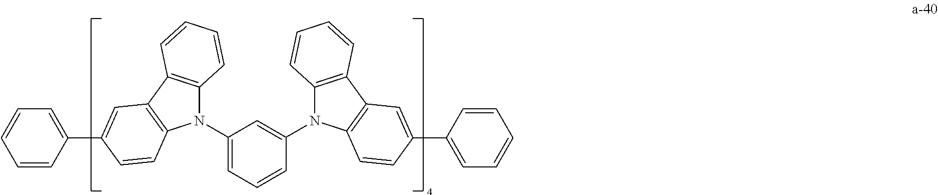

The light emission host used in the present invention, may be a well-known low molecular weight compound or a polymer having a repeating unit, or may be a low molecular weight compound having a polymerizable group, for example, a vinyl group of an epoxy group (polymerizable light emission host). However, the molecular weight is preferably low when a polymer material is used, because swelling, gel formation or a condition in which the solvent is difficult to be removed tends to occur due to the incorporation of the solvent in the compound. Specifically, the molecular weight of the material at the time of coating is preferably 1500 or less and more preferably 1000 or less.

A well-known host compound which may be used in combination is preferably a compound exhibiting a hole transport or electron transport function, preventing elongation of a light emission wave length, as well as having a high Tg (glass transition temperature). Examples of such a well-known host compound have been disclosed, for example, in the following documents.

For example, JP-A 2001-257076, JP-A 2002-308855, JP-A 2001-313179, JP-A 2002-319491, JP-A 2001-357977, JP-A 2002-334786, JP-A 2002-8860, JP-A 2002-334787, JP-A 2002-15871, JP-A 2002-334788, JP-A 2002-43056, JP-A 2002-334789, JP-A 2002-75645, JP-A 2002-338579, JP-A 2002-105445, JP-A 2002-343568, JP-A 2002-141173, JP-A 2002-352957, JP-A 2002-203683, JP-A 2002-363227, JP-A 2002-231453, JP-A 2003-3165, JP-A 2002-234888, JP-A 2003-27048, JP-A 2002-255934, JP-A 2002-260861, JP-A 2002-280183, JP-A 2002-299060, JP-A 2002-302516, JP-A 2002-305083, JP-A 2002-305084 and JP-A 2002-308837.

### <<Light Emission Dopant>>

The light emission dopant which may be used in the present invention will be explained.

As an emission dopant, a fluorescent dopant or a phosphorescence dopant may be employed. In order to obtain an organic EL element exhibiting a higher emission efficiency, it is preferable that the emission dopant employed in the emission layer or emission unit of the organic EL element contains a phosphorescent dopant, while the host compound described above is simultaneously contained.

A phosphorescent dopant may be appropriately selected from the well known phosphorescent dopants to be used in the light emission layer of an organic EL element.

The phosphorescent dopant is preferably a complex containing a metal of Group 8-10 of the periodic table, and more preferably an iridium compound, an osmium compound, a platinum compound (a platinum complex compound) or a rare-earth metal complex. Of these, most preferable is an iridium compound.

Specific examples of a compound used as a phosphorescent dopant will be below, however, the present invention is not limited thereto. These compounds can be synthesized, for example, according to a method described in Inorg. Chem., 40, 1704-1711.

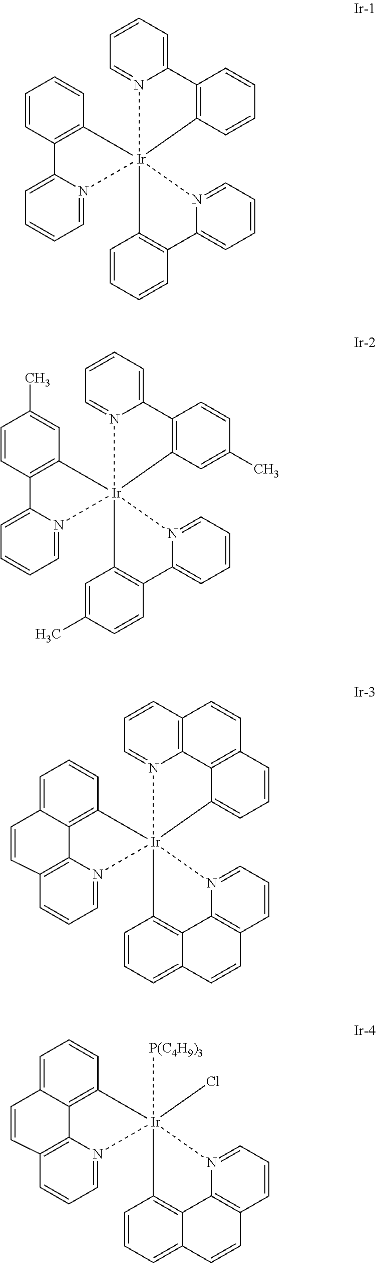

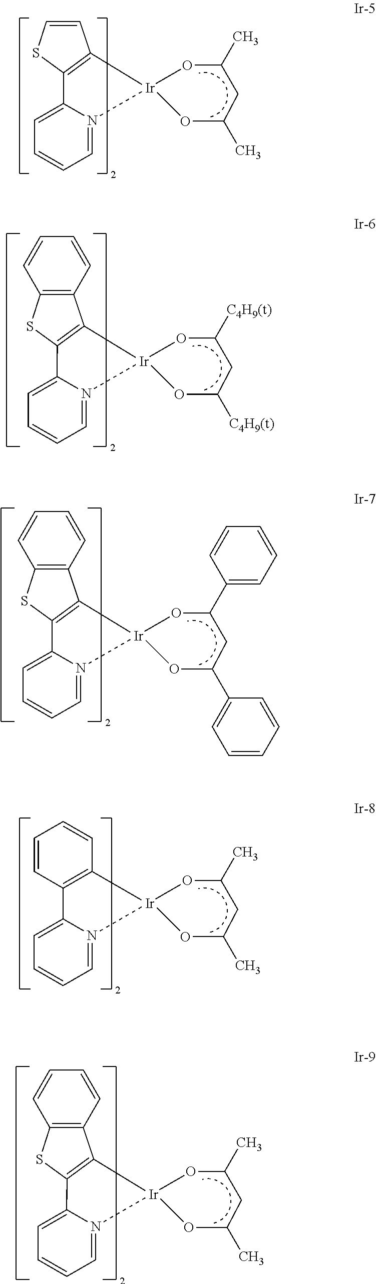

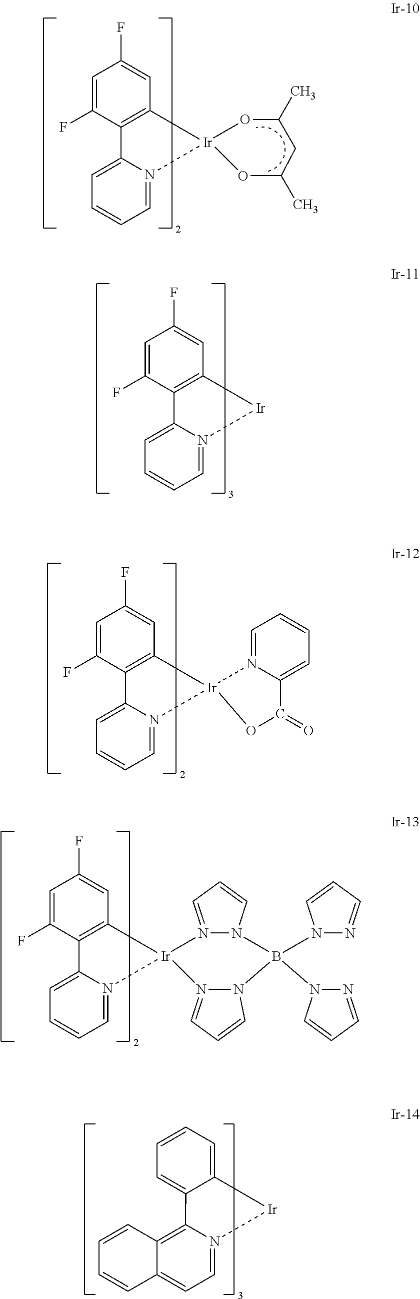

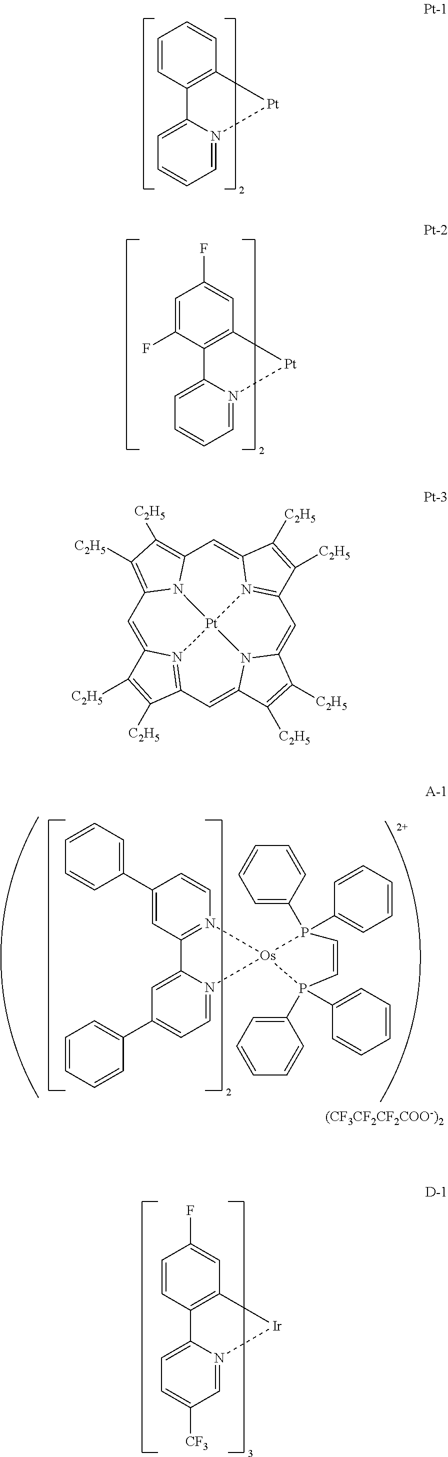

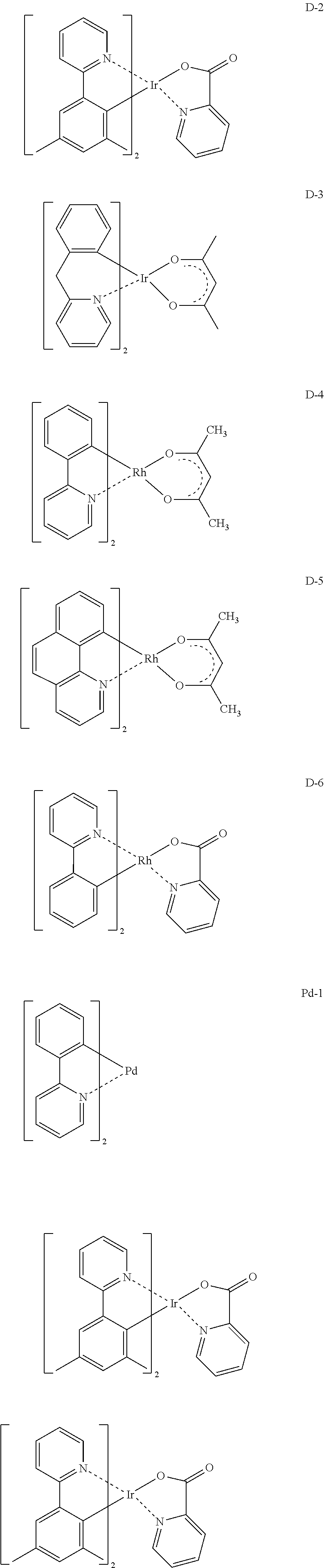

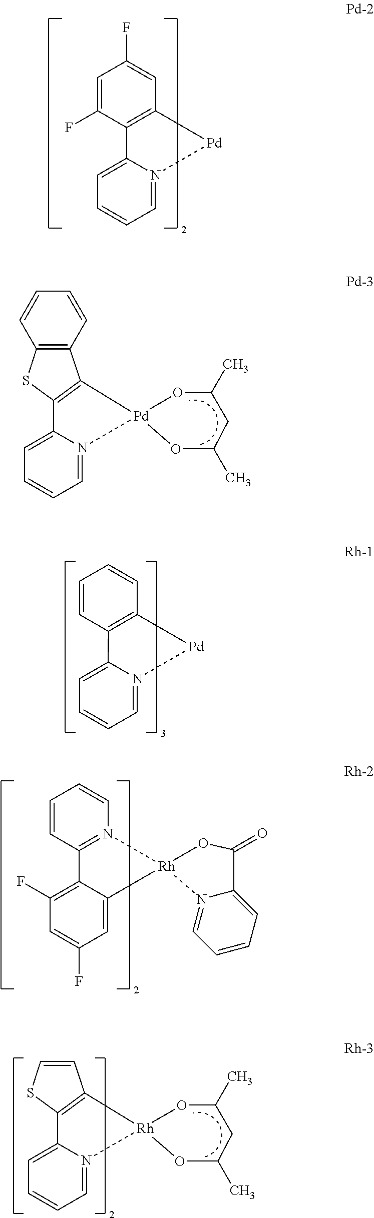

### <<Injection Layer: Electron Injection Layer, Positive Hole Injection Layer>>

An injection layer is provided when it is necessary and includes an electron injection layer which may be arranged between a cathode and an emission layer or an electron transport layer and a hole injection layer which may be arranged between an anode and an emission layer or a hole transport layer, as described above. An injection layer is a layer which is arranged between an electrode and an organic layer to decrease an driving voltage and to improve an emission luminance, which is detailed in “Electrode materials” in volume 2, chapter 2 (pp. 123-166) of “Organic EL Elements and Industrialization Front thereof (Nov. 30, 1998, published by N. T. S. Inc.)”, and includes descriptions on a positive hole injection layer (an anode buffer layer) and an electron injection layer (a cathode buffer layer).

An anode buffer layer (a positive hole injection layer) is also detailed in such as JP-A No. 09-45479, JP-A No. 09-260062 and JP-A No. 08-288069, and specific examples include such as a phthalocyanine buffer layer represented by such as copper phthalocyanine, an oxide buffer layer represented by such as vanadium oxide, an amorphous carbon buffer layer, and a polymer buffer layer employing conductive polymer such as polyaniline (emeraldine) and polythiophene.

A cathode buffer layer (an electron injection layer) is also detailed in such as JP-A No. 06-325871, JP-A No. 09-17574 and JP-A No. 10-74586, and specific examples include a metal buffer layer represented by strontium, aluminum and so on, an alkali metal compound buffer layer represented by lithium fluoride, an alkali metal earth compound buffer layer represented by magnesium fluoride and an oxide buffer layer represented by aluminum oxide. The above-described buffer layer (injection layer) is preferably a very thin layer, and the layer thickness is preferably in a range of 0.1 nm-5 μm although it depends on a raw material.

### <<Blocking Layer: Hole Blocking Layer, Electron Blocking Layer>>

A blocking layer is provided in addition to a principal layer arrangement of the organic compound layer as described above. There is, for example, a hole blocking layer described in such as JP-A No. 11-204258 and JP-A No. 11-204359 and p. 237 of “Organic EL Elements and Industrialization Front Thereof (Nov. 30, 1998), published by NTS. Inc.)”.

A hole blocking layer, in a broad meaning, is provided with a function of electron transport layer, being comprised of a material having a function of transporting an electron but a very small ability of transporting a positive hole, and can improve the recombination probability of an electron and a positive hole by blocking a positive hole while transporting an electron. Further, an arrangement of an electron transport layer described later can be appropriately utilized as a hole blocking layer which may be used in the present invention.

The hole blocking layer of the organic EL element of the present invention is preferably provided adjacent to the light emission layer.

It is preferred that the hole blocking layer contains an azacarbazole derivative recited as an example of a host compound.

When the element comprises a plurality of emission layers of different emission colors, the emission layer emitting light of which emission maximum wavelength is shortest is preferably arranged nearest to the anode among the all emission layers, however, in such a case, a hole blocking layer is preferably arranged additionally between said shortest wavelength layer and an emission layer second nearest to the anode. Further, not less than 50 weight % of the compound contained in the hole blocking layer arranged at said position has an ionization potential larger by 0.3 eV or more against the ionization potential of the host compound of the aforesaid shortest wavelength layer.

The ionization potential is defined by an energy required to release an electron existing on the HOMO (highest occupied molecular orbit) level to a vacuum level, and for example, can be determined according to the following method.

(1) By use of Gaussian 98 (Gaussian 98, Revision A. 11. 4, M. J. Frisch, et al, Gaussian, Inc., Pittsburgh, Pa., 2002), which is a molecular orbit calculation software manufactured by Gaussian, Inc., USA; a value calculated by performing structural optimization (converted value of eV unit), the second place of decimals of which is rounded off, is defined as an ionization potential.

(2) An ionization potential can be also determined by being directly measured by means of photoelectron spectroscopy. Foe example, a low energy electron spectrometer “Model AC-1” manufactured by Riken Keiki Co., Ltd., or a method known as ultraviolet photoelectron spectroscopy can be preferably utilized.

On the other hand, an electron blocking layer is, in a broad meaning, provided with a function of a positive hole transport layer, being comprised of a material having a function of transporting a positive hole but a very small ability of transporting an electron, and can improve the recombination probability of an electron and a positive hole by blocking an electron while transporting a positive hole. Further, an arrangement of a hole transport layer described later can be appropriately utilized as an electron blocking layer. Thickness of the hole blocking layer and electron transport layer is preferably 3 to 100 nm, and more preferably 5 to 30 nm.

### <<Hole Transport Layer>>

A hole transport layer contains a material having a function of transporting a positive hole, and in a broad meaning, a positive hole injection layer and an electron blocking layer are also included in a positive hole transport layer. A single layer of or plural layers of a positive hole transport layer may be provided.

A hole transport material is those having any one of a property to inject or transport a positive hole or a barrier property to an electron, and may be either an organic material or an inorganic material. For example, listed are a triazole derivative, an oxadiazole derivative, an imidazole derivative, a polyarylalkane derivative, a pyrazoline derivative, a pyrazolone derivative, a phenylenediamine derivative, a arylamine derivative, an amino substituted chalcone derivative, an oxazole derivatives, a styrylanthracene derivative, a fluorenone derivative, a hydrazone derivative, a stilbene derivative, a silazane derivative, an aniline type copolymer, or conductive high molecular oligomer, specifically preferably such as thiophene oligomer.

As a hole transport material, those described above can be utilized, however, it is preferable to utilize a porphyrin compound, an aromatic tertiary amine compound and a styrylamine compound, and specifically preferably an aromatic tertiary amine compound.

Typical examples of an aromatic tertiary amine compound and a styrylamine compound include: N,N,N′,N′-tetraphenyl-4,4′-diaminophenyl; N,N′-diphenyl-N,N′-bis(3-methylphenyl)-(1,1′-biphenyl)-4,4′-diamine (TDP); 2,2-bis(4-di-p-tolylaminophenyl)propane; 1,1-bis(4-di-p-tolylaminophenyl)cyclohexane; N,N,N′,N′-tetra-p-tolyl-4,4′-diaminobiphenyl; 1,1-bis(4-di-p-tolylaminophenyl)-4-phenylcyclohexane; bis(4-dimethylamino-2-methylphenyl)phenylmethane; bis(4-di-p-tolylaminophenyl)phenylmethane; N,N′-diphenyl-N,N′-di(4-methoxyphenyl)-4,4′-diaminobiphenyl; N,N,N′,N′-tetraphenyl-4,4′-diaminodiphenylether; 4,4′-bis(diphenylamino)quadriphenyl; N,N,N-tri(p-tolyl)amine; 4-(di-p-tolylamino)-4′-[4-(di-p-tolylamino)styryl]stilbene; 4-N,N-diphenylamino-(2-diphenylvinyl)benzene; 3-methoxy-4′-N,N-diphenylaminostilbenzen; and N-phenylcarbazole, in addition thereto, those having two condensed aromatic rings in a molecule described in U.S. Pat. No. 5,061,569, such as 4,4′-bis[N-(1-naphthyl)-N-phenylamino]biphenyl (NDP), and 4,4′,4″-tris[N-(3-methylphenyl)-N-phenylamino]triphenylamine (MTDATA), in which three of triphenylamine units are bonded in a star burst form, described in JP-A No. 04-308688.

A polymer in which the material mentioned above is introduced in the polymer chain or a polymer having the material as the polymer main chain can be also used. As the hole injecting material or the hole transporting material, inorganic compounds such as p-type Si and p-type SiC are usable.

A so-called p-type hole blocking layer as disclosed in JP-A 11-251067 or described in the literature of J. Huang et al. (Applied Physics Letters 80(2002), p. 139) is also applicable. In the present invention, these materials are preferably utilized since an emitting element exhibiting a higher efficiency is obtained.

This hole transport layer can be provided by forming a thin layer made of the above-described hole transport material according to a method known in the art such as a vacuum evaporation method, a spin coating method, a cast method, an inkjet method and a LB method. The layer thickness of a hole transport layer is not specifically limited, however, is generally 5 nm to 5 μm, and preferably 5 to 200 nm. This hole transport layer may have a single layer structure comprised of one or two or more types of the above described materials.

A hole transport layer having high p-type property doped with impurity can be utilized. Example thereof includes those described in JP-A No. 04-297076, JP-A No. 2000-196140, JP-A No. 2001-102175, and J. Appl. Phys., 95, 5773 (2004) and so on.

It is preferable to employ such a hole transport layer having high p-type property, since an element with lower power consumption can be prepared in this invention.

### <Electron Transport Layer>

An electron transport layer is composed of a material having a function of transporting an electron, and in a broad meaning, an electron injection layer and a hole blocking layer are also included in an electron transport layer. A single layer of or plural layers of an electron transport layer may be provided.

The electron transport material (it works as a hole blocking layer, simultaneously), which is employed in a single electron transport layer and an electron transport layer provided adjacent to cathode side with respect to emission layer when it is used as plural layers, is sufficient to have a function to transmit an electron injected from a cathode to an emission layer, and compounds conventionally known in the art can be utilized by arbitrarily selection as a material thereof. Any one can be employed by selecting from conventionally known compounds as its material. Examples of a material include such as a nitro-substituted fluorene derivative, a diphenylquinone derivative, a thiopyrandioxide derivative, carbodiimide, a fleorenylidenemethane derivative, anthraquinonedimethane and anthrone derivatives. Further, a thiazole derivative in which an oxygen atom in the oxadiazole ring of the above-described oxadiazole derivative is substituted by a sulfur atom, and a quinoxaline derivative having a quinoxaline ring which is known as an electron attracting group can be utilized as an electron transport material. Polymer materials, in which these materials are introduced in a polymer chain or these materials form the main chain of polymer, can be also utilized.

Further, a metal complex of a 8-quinolinol derivative such as tris(8-quinolinol)aluminum (Alq), tris(5,7-dichloro-8-quinolinol)aluminum, tris(5,7-dibromo-8-quinolinol)aluminum, tris(2-methyl-8-quinolinol)aluminum, tris(5-methyl-8-quinolinol)aluminum and bis(8-quinolinol)zinc (Znq); and metal complexes in which a central metal of the aforesaid metal complexes is substituted by In, Mg, Cu, Ca, Sn, Ga or Pb, can be also utilized as an electron transport material. Further, metal-free or metal phthalocyanine, or those the terminal of which is substituted by an alkyl group and a sulfonic acid group, can be preferably utilized as an electron transport material.

Further, distyrylpyrazine derivative, which has been exemplified as a material of an emission layer, can be also utilized as an electron transport material, and, similarly to the case of a positive hole injection layer and a positive hole transport layer, an inorganic semiconductor such as an n-type-Si and an n-type-SiC can be also utilized as an electron transport material.

The electron transport layer can be provided by forming a thin layer made of the above-described electron transport material according to a method known in the art such as a vacuum evaporation method, a spin coating method, a cast method, an inkjet method and a LB method. The layer thickness of an electron transport layer is not specifically limited; however, is generally 5 nm-5 μm, preferably 5-200 nm. This electron transport layer may have a single layer structure comprised of one or not less than two types of the above described materials.

An electron transport layer having high n-type property doped with impurity can be utilized. Example thereof includes those described in JP-A No. 04-297076, JP-A No. 10-270172, JP-A No. 2000-196140, JP-A No. 2001-102175, and J. Appl. Phys., 95, 5773 (2004) and so on.

It is preferable to employ such an electron transport layer having high n-type property, since an element with lower power consumption can be prepared in the present invention.

### <Mode>

As an anode according to an organic EL element of the present invention, those comprising metal, alloy, a conductive compound, which has a large work function (not less than 4 eV), and a mixture thereof as an electrode substance are preferably utilized. Specific examples of such an electrode substance include a conductive transparent material such as metal like Au, CuI, indium tin oxide (ITO), SnO₂ and ZnO. Further, a material such as IDIXO (In₂O₃—ZnO), which can prepare an amorphous and transparent electrode, may be also utilized.

As for an anode, these electrode substances may be made into a thin layer by a method such as evaporation or sputtering and a pattern of a desired form may be formed by means of photolithography, or in the case of requirement of pattern precision is not so severe (not less than 100 μm), a pattern may be formed through a mask of a desired form at the time of evaporation or sputtering of the above-described substance. Alternatively, when a material is able to be applied by coating, such as an organic conductive material, a wet method, for example, a printing method or a coating method, may be used. When emission is taken out of this anode, the transmittance is preferably set to not less than 10% and the sheet resistance as an anode is preferably not more than a several hundreds Ω/□. Further, although the layer thickness depends on a material, it is generally selected in a range of 10-1,000 nm and preferably of 10-200 nm.

### <Cathode>

On the other hand, as a cathode according to the present invention, metal, alloy, a conductive compound and a mixture thereof, which have a small work function (not more than 4 eV), are utilized as an electrode substance. Specific examples of such an electrode substance includes such as sodium, sodium-potassium alloy, magnesium, lithium, a magnesium/copper mixture, a magnesium/silver mixture, a magnesium/aluminum mixture, a magnesium/indium mixture, an aluminum/aluminum oxide (Al₂O₃) mixture, indium, a lithium/aluminum mixture and rare earth metal.

Among them, with respect to an electron injection property and durability against such as oxidation, preferable are a mixture of electron injecting metal with the second metal which is stable metal having a work function larger than electron injecting metal, such as a magnesium/silver mixture, a magnesium/aluminum mixture, a magnesium/indium mixture, an aluminum/aluminum oxide (Al₂O₃) mixture and a lithium/aluminum mixture, and aluminum. The cathode can be produced by forming a thin layer of these electrode materials via vacuum evaporation or sputtering.

Further, the sheet resistance as a cathode is preferably not more than a several hundreds Ω/□ and the layer thickness is generally selected in a range of 10 nm-5 μm and preferably of 50-200 nm. Herein, to transmit emission, either one of an anode or a cathode of an organic EL element is preferably transparent or translucent to improve the emission luminance.

A transparent or translucent cathode may be prepared by a method in which the above mentioned metal is provided on the anode with a thickness of 1 to 20 nm and then electroconductive transparent material described as the anode. An element having both transparent anode and cathode may be prepared by applying this method.

### <Substrate>

A substrate (also referred to as Base Body, Base Plate, Base Material or Support) according to an organic EL element of the present invention is not specifically limited with respect to types of such as glass and plastics being transparent or opaque, however, a substrate preferably utilized includes such as glass, quartz and transparent resin film. A specifically preferable substrate is resin film capable of providing an organic EL element with a flexible property.

Resin film includes polyester such as polyethylene terephthalate (PET) and polyethylene naphthalate (PEN), polyethylene, polypropylene, cellophane, cellulose ester and its derivatives such as cellulose diacetate, cellulose triacetate, cellulose acetate butylate, cellulose acetate propionate (CAP), cellulose acetate phthalate (TAC),and cellulose nitrate, polyvinylidene chloride, polyvinylalcohol, polyethylenevinylalcohol, syndiotactic polystyrene, polycarbonate, norbornane resin, polymethylpentene, polyetherketone, polyimide, polyether sulfone (PES), polyphenylene sulfide, polysulfones, polyether imide, polyetherketone imide, polyamide, fluorine resin, nylon, polymethyl methacrylate, acryl or acrylates, cyclo-olefin resin such as ARTON (commercial name, manufactured by JSR Corp.) or APEL (commercial name, manufactured by Mitsui Chemicals Inc.).

On the surface of a resin film, an inorganic or organic cover layer or a hybrid cover layer containing the both may be formed, and the film is preferably provided with a high barrier ability having a vapor permeability of not more than 0.01 g/m²·/day·atm, and more preferably a high barrier ability having an oxygen permeability of not more than 10⁻³ g/m²/day as well as a vapor permeability of not more than 10⁻⁵ g/m²/day.

Any materials capable of preventing penetration of substance causing degradation of the element such as moisture and oxygen are usable for forming the barrier layer. For example, silicon oxide, silicon dioxide and silicon nitride are usable. It is more preferable to give a laminated layer structure composed of such the inorganic layer and a layer of an organic material to the barrier layer for improving the fragility of the layer. It is preferable that the both kinds of layers are alternatively piled for several times though there is no limitation as to the laminating order of the inorganic layer and the organic layer.

The method for forming the barrier layer is not specifically limited and, for example, a vacuum evaporation method, a sputtering method, a reaction sputtering method, a molecular beam epitaxy method, a cluster-ion beam method, an ion plating method, a plasma polymerization method, an atmospheric pressure plasma polymerization method, a plasma CVD method, a laser CVD method, a thermal CVD method and a coating method are applicable, and the atmospheric pressure plasma polymerization method such as that described in JP A No. 2004-68143 is particularly preferable.

As the opaque substrate, for example, a plate of metal such as aluminum and stainless steel, a film or plate of opaque resin and a ceramic substrate are cited.

External quantum efficiency of an organic EL element of the present invention at room temperature is preferably not less than 1%, and more preferably not less than 5%. Herein, external quantum efficiency (%)=a number of photons emitted outside of an organic EL element/a number of electrons flown in an organic EL element×100.

Further, a hue improving filter such as a color filter may be utilized together, and a color conversion filter, which converts emission color from an organic EL element into multicolor by use of a fluorescent substance, may be also utilized together. In the case of utilizing a color conversion filter, λmax of emission of an organic EL element is preferably not more than 480 nm.

### <<Sealing>>

As the sealing means, a method for pasting together with a sealing material, the electrodes and the substrate by an adhesive agent is applicable.

The sealing material is placed so as to cover the displaying area of the organic EL element and may have a flat plate shape or a concave plate shape, and the transparence and the electric insulation property of it are not specifically limited.

A glass plate, polymer plate, polymer film, metal plate and metal film can be cited. As the glass plate, a plate of soda-lime glass, barium strontium-containing glass, lead glass, alumino silicate glass, boron silicate glass, barium-boron silicate glass and quartz are usable practically. As the polymer plate, a plate of polycarbonate, acryl resin, poly(ethylene terephthalate), polyether sulfide and polysulfone are usable. As the metal plate, a plate composed of one or more kinds of metal selected from stainless steel, iron, copper, aluminum, magnesium, nickel, zinc, chromium, titanium, molybdenum, silicon, germanium and tantalum and an alloy of them are cited.

A polymer film and a metal film are preferably used by which the element can be made thinner in the present invention. The polymer film having an oxygen permeability of not more than 1×10⁻³ ml/(m²·24 hr), measured by a method stipulated by JIS K 7126-1987, and a water vapor permeability of not more than 1×10⁻³ g/(m²·24 hr) at 25±0.5° C., 90±2% RH measured by a method stipulated by JIS K 7129-1992.

A sandblast treatment and a chemical etching treatment are applicable for making the sealing material into the concave shape.

A photo-curable and thermo-curable adhesive agents containing a reactive vinyl group of acryl type oligomer and a methacryl type oligomer, and a moisture curable adhesive agent such as 2-cyanoacrylate can be cited as the adhesive agent. Epoxy type thermally and chemically (two liquid type) curable adhesive agents are applicable. Hot-melt type polyamide, polyester and polyolefin adhesive agents are applicable. Cationic curable type UV curable epoxy adhesive agent is also usable.

The organic EL element is degraded by heat in some cases, therefore, the adhesive agent capable of being cured to adhere within the temperature range of from room temperature to 80° is preferred. A moisture absorbing agent may be dispersed in the adhesive agent. Coating of the adhesive agent onto the adhering portion may be performed by a dispenser available on the market or printing by a screen printing.

It is preferable that an inorganic or organic layer is provided on outside of the electrode placed on the side of facing to the substrate through an organic layer so as to cover the electrode and the organic layer and contact with the substrate to form a sealing layer. In such the case, the material for forming the sealing layer may be a material having a function to inhibit permeation of a substance causing degradation such as water and oxygen, and silicon oxide, silicon dioxide and silicon nitride are usable for example. The layer preferably has a laminated structure composed of an inorganic material and an organic material.

The method of forming such a layer is not specifically limited, and applicable is a method, for example, a vacuum evaporation method, a sputtering method, a reaction sputtering method, a molecular beam epitaxy method, a cluster-ion beam method, an ion plating method, a plasma polymerization method, an atmospheric pressure plasma polymerization method, a plasma CVD method, a laser CVD method, a thermal CVD method and a coating method.

In the space between the sealing material and the displaying portion of the organic EL element, an inactive gas such as nitrogen and argon or an inactive liquid such as silicone oil is preferably injected. The space may be made vacuum. A moisture absorbing compound may be enclosed in the element.

Examples of the moisture absorbing compound include a metal oxide such as sodium oxide, potassium oxide, calcium oxide, barium oxide, magnesium oxide and aluminum oxide, a sulfate such as sodium sulfate, calcium sulfate, magnesium sulfate and cobalt sulfate, a metal halide such as calcium chloride, magnesium chloride, cesium fluoride, tantalum fluoride, cerium bromide, magnesium bromide, barium iodide and magnesium iodide, and a perchlorate such as barium perchlorate and magnesium perchlorate. Anhydrate is preferable as to the sulfate, halide and perchlorate.

### <<Manufacturing Method of Organic EL Element>>

The manufacturing method of the organic EL element of the present invention is characterized in that, in the organic laminate sandwiched between an anode and a cathode, at least a light emission layer is formed via a wet process, and more preferably four or more layers including the light emission layer each are formed via a wet process. It is also preferable that whole the organic laminate is formed via a wet process. Examples of a layer contained in the organic laminate include: a hole injection layer, a hole transport layer, a hole blocking layer, an electron injection layer, an electron transport layer and an electron blocking layer. A wet process as referred to in the present invention means a method in which the layer forming material is supplied in the form of a liquid and then layer forming is carried out.

As an example of a preparation method of an organic EL element of the present invention, a preparation method of an organic EL element, comprising anode/hole injection layer/hole transport layer/light emission layer/electron transport layer/electron injection layer/cathode, will be described.

First, on an appropriate substrate, a thin layer comprising a desired electrode substance such as an anode electrode substance is formed by means of vacuum evaporation or sputtering so as to make a layer thickness of not more than 1 μm and preferably of 10-200 nm, whereby an anode is prepared.

Next, organic compound thin layers (organic layers), for example, a hole injection layer, a hole transport layer, an light emission layer, a hole blocking layer, an electron transport layer and an electron injection layer, which are organic EL element constituting layers, are formed on this layer.

Examples of a method of forming these layers include, as described above: a vacuum evaporation method and a wet process (such as a spin coat method, a die coat method, a casting method, an inkjet method, a spray method and a printing method). In the present invention, preferable is layer formation via a coating method, for example, a spin coat method, a die coat method, an inkjet method, a spray method and a printing method.

In the manufacturing of an organic EL element of the present invention, the layer other than a light emission layer may be formed via a wet process. Examples of a solvent liquid to dissolve or disperse the material include: ketones such as methyl ethyl ketone, cyclohexanone, cyclopentanone and 2-pentanone; aliphatic esters such as ethyl acetate and butyl acetate; halogenated hydrocarbons such as dichlorobenzene; aromatic hydrocarbons such as toluene, xylene, mesitylene, cyclohexylbenzene and anisole; aliphatic hydrocarbons such as cyclohexane, decalin and dodecane; organic solvents such as DMF and DMSO; and water.

After formation of these layers, a thin layer comprising a cathode electrode substance is formed thereon by means of such as evaporation or sputtering so as to make a layer thickness of 1 μm or less, preferably 50-200 nm to provide a cathode, whereby a desired organic EL element can be prepared.

Further, reversing the preparation order, it is also possible to prepare layers in the order of a cathode, an electron injection layer, an electron transport layer, a light emission layer, a hole transport layer, a hole injection layer and an anode. When a direct current voltage is applied on the multicolor display device thus prepared, emission can be observed by application of a voltage of approximately 2 to 40 V setting an anode to + (plus) polarity and a cathode to − (minus) polarity. Further, in the case of alternating current voltage may also be applied. Herein, the wave shape of alternating current may be arbitrary.

### <<Protection Layer and Protection Plate>>

For raising the mechanical strength of the element, a protection layer or a protection plate may be provided on outside of the sealing layer of the side facing to the substrate through the organic layer or the outside of the sealing film. Such the protection layer or plate is preferably provided since the strength of the element is not always so high when the sealing is carried out by the foregoing sealing layer. The glass plate, polymer plate, polymer film and plate, and metal film and plate the same as those to be used for sealing are usable for such the protection material. Polymer film is preferably used from the viewpoint of light weight and less thickness.

### <<Light Out-Coupling>>

Generally it is said that in the organic EL element of the present invention, light is emitted in a layer of which refractive index is higher (the refractive index is about 1.7 to 2.1) than that of air, and only 15 to 20% of the light emitted in the light emission layer can be taken out. This is because the light which enters into the interface (interface of a transparent substrate and air) with the angle θ larger than a critical angle cannot be taken out of the element due to the total internal reflection, or because the light is totally reflected between the transparent substrate and the transparent electrode or between the transparent substrate and the light emission layer, resulting in being wave-guided in the transparent electrode or in the light emission layer to get away to the side of the element.

Examples of a method to improve the light out-coupling efficiency include: a method to form concavity and convexity on the surface of the transparent substrate to prevent total internal reflection at the interface between the transparent substrate and air (for example, refer to U.S. Pat. No. 4,774,435); a method to provide a light converging function to the substrate (for example, refer to JP-A No. 63-314795); a method to provide a reflecting surface on the side of the element (for example, refer to JP-A No. 01-220394); a method to provide a flat layer between the substrate and the light emission layer, the flat layer having an intermediate refractive index to form an anti-reflection layer (for example, refer to JP-A No. 62-172691); a method to provide a flat layer having a low refractive index between the substrate and the light emission layer (for example, JP-A No. 2001-202827); and a method to provide a diffraction grating between any of the substrate, transparent electrode and light emission layer (including the interlayer between the substrate and out side air) (for example refer to JP-A No. 11-283751).

These methods can be used in combination with the organic electroluminescence element of the present invention. Also, a method of forming a flat layer having a lower refractive index than that of the substrate between the substrate and the light emission layer, or a method of forming a diffraction grating between any of the substrate, transparent electrode and light emission layer (including the interlayer between the substrate and out side air) can be preferably used.

In the present invention, an organic EL element exhibiting a further high luminance or durability can be obtained via the combination of these methods.

By providing a low refractive index medium having a thickness thicker than the wavelength of the light between the transparent electrode and the transparent substrate, the light-extracting efficiency becomes larger with decreasing the refractive index of the low refractive index medium.

As a low refractive index layer, aerogel, porous silica, magnesium fluoride and fluorine-containing polymer, are cited, for example. Since the refractive index of the transparent substrate is generally 1.5 to 1.7, the refractive index of the low refractive index layer is preferably 1.5 or less and more preferably 1.35 or less.

The thickness of a low refractive index medium is preferably more than twice of the wavelength of the light in the medium, because when the thickness of the low refractive index medium, where the electromagnetic wave exuded as an evanescent wave enters into the transparent substrate, and the effect of the low refractive index layer is reduced.

The method to provide a diffraction grating at the interface where the total internal reflection occurs or in some of the medium has a feature that the effect of enhancing the light-extracting efficiency is high. The intention of this method is to take out the light which cannot come out due to such as total internal reflection between the layers among the light emitted in the light emission layer, by providing a diffraction grating between any of the layers or in any of the mediums (in the transparent substrate or in the transparent electrode), using the property of the diffraction grating that it can change the direction of light to a specified direction different from the direction of reflection due to so-called Bragg diffraction such as primary diffraction or secondary diffraction.

The diffraction grating to be provided preferably has a two-dimensional periodic refractive index. This is because, since the light is emitted randomly to any direction, only the light proceeds to a specific direction can be diffracted when a generally used one-dimensional diffraction grating having a periodic refractive index only in a specific direction is used, whereby the light-extracting efficiency is not largely increases. However, by using diffraction grating having a two-dimensionally periodic refractive index, the light proceeds any direction can be diffracted, whereby the light-extracting efficiency is increased.

The diffraction grating may be provided between any of the layers on in any of the mediums (in the transparent substrate or in the transparent electrode), however, it is preferably provided in the vicinity of the organic light emission layer where the light is emitted. The period of the diffraction grating is preferably ½ to 3 times of the wavelength of the light in the medium.

The array of the diffraction grating is preferably two-dimensionally repeated, for example, as in the shape of a square lattice, a triangular lattice, or a honeycomb lattice.

### <<Light-Condensing Sheet>>

In the organic electroluminescence element of the present invention, the luminance in the specified direction, for example, the front direction against the emitting plane of the element can be increased, for example, by processing to form a structure of a micro-lens array or in combination with a so-called light-condensing sheet on the light-extracting side surface of the substrate.

As an example of a micro-lens array, quadrangular pyramids 30 μm on a side and having a vertex angle of 90° are two-dimensionally arranged on the light extracting side surface of the substrate. The side of the quadrangular pyramids is preferably 10 to 100 μm. When the length of the side is shorter than the above range, the light is colored due to the effect of diffraction, and when it is longer than the above range, it becomes unfavorably thick.

As a light-condensing sheet, the one practically applied for an LED backlight of a liquid crystal display is applicable. Examples of such a sheet include a brightness enhancing film (BEF) produced by SUMITOMO 3M Inc. As the shape of the prism, triangle-shaped strip having a vertex angle of 90° and a pitch of 50 μm, the one having round apexes, or the one having a randomly changed pitch may be included.

In order to control the luminous radiation angle of the light emitting element, a light diffusion plate and a film may be used in combination with the light-condensing sheet. For example, a diffusion film (light-up) produced by KIMOTO Co., Ltd. can be used.

### <<Application>>

The organic EL element of the invention can be used as a displaying device and various kinds of light source. As the light source, domestic illumination, car interior illumination, backlight of watches or liquid crystal displays, sign boards, signals, light source of photo memories, light source of electrophotographic copying machine, light source of light communication processor and light source of light sensors, though the use is not limited to the above. Specifically, the device is suitably used for a backlight of the liquid crystal display or a light source of an illuminator.

If needed, the organic EL element of the present invention may undergo patterning via a metal mask or an ink-jet printing method during film formation. When the patterning is carried out, only an electrode may undergo patterning, an electrode and a light emitting layer may undergo patterning, or all element layers may undergo patterning. During preparation of the element, it is possible to employ conventional methods.

Color of light emitted by the organic EL element of the present invention and compounds according to the present invention is specified as follows. In Fig. 4.16 on page 108 of “Shinpen Shikisai Kagaku Handbook (New Edition Color Science Handbook)” (edited by The Color Science Association of Japan, Tokyo Daigaku Shuppan Kai, 1985), values determined via a spectroradiometric luminance meter CS-1000 (produced by Konica Minolta Sensing Inc.) are applied to the CIE chromaticity coordinate, whereby the color is specified.

Further, when the organic EL element of the present invention is a white element, “white”, as described herein, means that when 2-degree viewing angle front luminance is determined via the aforesaid method, chromaticity in the CIE 1931 Color Specification System is within the region of X=0.33±0.07 and Y=0.33±0.07. In the light emission layer of the organic EL element of the present invention, a light emission host and at least one kind of a light emission dopant as a guest material are preferably contained.

### Examples

The present invention will now be explained with referring to examples, however, the present invention is not limited thereto.

### Example 1

The structures of the compounds used in the examples will be shown below.

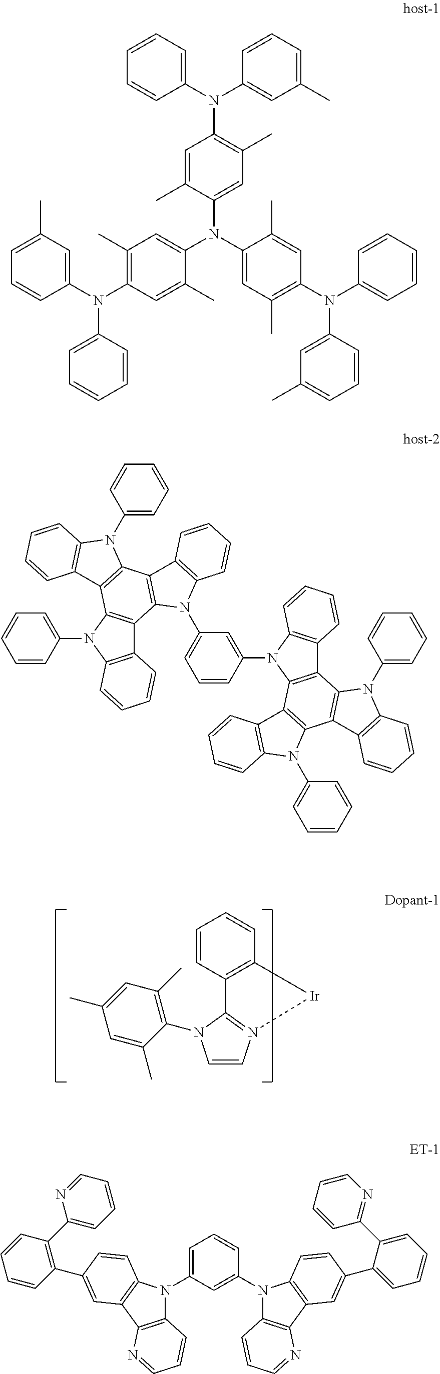

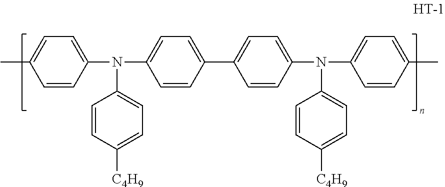

### <<Preparation of Organic EL Element 101>>

Patterning was carried out on a 100 mm×100 mm×1.1 mm glass substrate on which 100 nm thick ITO (indium tin oxide) film was formed as an anode. The transparent substrate having thereon the transparent 11′O electrode was cleaned ultrasonically in normal propyl alcohol, dried with desiccated nitrogen gas, and subjected to UV ozone cleaning for 5 minutes.

On this transparent substrate, a 70% aqueous solution of poly (3,4-ethylenedioxithiophene)-polystyrene sulfonate (PEDOT/PSS: Baytron P A1 4083 produced by Bayer AG) diluted by pure water was spin coated on the transparent substrate at 3000 rpm for 30 seconds, followed by drying at 200° C. for 1 hour, to form a hole injection layer of a thickness of 30 nm.

Subsequently, the substrate was moved in a nitrogen atmosphere glove box, and a solution obtained by dissolving compound HT-1 (50 mg) in 10 ml of monochlorobenzene was spin coated (thickness of 20 nm) at 1500 rpm for 30 seconds, followed by drying at 160° C. for 30 minutes under a nitrogen atmosphere, whereby a hole transport layer was obtained.

Subsequently, a solution obtained by dissolving compound a-6 (100 mg) which was a light emission host and Dopant-1 (19 mg) which was a blue light emission dopant in 10 ml of ethylbenzene was spin coated (thickness of 50 nm) at 1500 rpm for 30 seconds, followed by drying at 120° C. for 30 minutes under a nitrogen atmosphere, whereby a blue light emission layer was obtained.

Further, the substrate was set in a vacuum evaporation apparatus, the vacuum chamber was evacuated to 4×10⁻⁴ Pa, and compound ET-1 was vacuum evaporated to form an electron transport layer of a thickness on 20 nm. Subsequently, a 1 nm LiF layer was vacuum evaporated as an electron injection layer, and a 110 nm aluminum layer was vacuum evaporated as a cathode, thus Organic EL element 101 was obtained.

### <<Production of Organic EL Elements 102-113>>

Organic EL elements 102-113 were prepared in the same manner as described for Organic EL elements 101 except that a-6, Dopant-1 and the solvent were changed to those listed in Table 1, while the mass ratio of the host compound and the dopant was kept constant (light emission host:light emission dopant=100:19) and the concentration of the solution was appropriately adjusted so as to obtain the same coating thickness when the solution was spin coated at 1500 rpm for 30 seconds, to obtain blue light emission layers.

### <<Evaluation of an Organic EL Element>>

For the prepared organic EL elements, evaluation was carried out with respect to an external quantum efficiency, a driving voltage, and an elevation in driving voltage under continuous operation, as follows.

### (External Quantum Efficiency)

A constant electric current of 2.5 mA/cm² was applied to each of the prepared organic EL elements, and an external extraction quantum efficiency (in %) was determined. Determination was carried out by employing a spectral radiance meter CS-1000 (produced by Konica Minolta Sensing Inc.). Determination results of the external quantum efficiencies of Organic EL elements 102-113 were subjected to relative comparison, with the value of Organic EL element 101 set at 100.

### (Driving Voltage)

The driving voltage of each organic EL element while a constant current of 2.5 mA/cm² is passed through the element at an ambient temperature (around 23-25° C.) was determined. The results were subjected to relative comparison, with the value of Organic EL element 101 set at 100.

### (Elevation in Driving Voltage Under Continuous Operation)

An electric current was passed through each organic EL element so as to obtain a front luminance of 2000 cd/m², and the element was continuously driven until the front luminance decreased to a half value of the initial value of 1000 cd/m². The difference in the driving voltage between the initial voltage and the voltage at termination of driving was obtained as the elevation in driving voltage under continuous operation. The evaluation criteria were as follows.

A Elevation in voltage under continuous operation is less than 0.5V.

B Elevation in voltage under continuous operation is 0.5V or more, but less than 1.0 V.

C Elevation in voltage under continuous operation is 1.0V or more, but less than 2.0 V.

D Elevation in voltage under continuous operation is 2.0 V or more.

TABLE 1

| Organic | | | Light | Light | Boiling | Saturation vapor | External | | Elevation | |
|---|---|---|---|---|---|---|---|---|---|---|
| EL | | Functional | emission | emission | point | pressure (20° C.) | quantum | Driving | in driving | |
| element | Solvent | group | host | dopant | (° C.) | (mmHg) | efficiency | voltage | voltage | Remarks |
| 101 | Ethylbenzene | | a-6 | Dopant-1 | 136.2 | 7.1 | 100 | 100 | D | Comp. |
| 102 | Toluene | | a-6 | Dopant-1 | 110.6 | 21.8 | 105 | 100 | D | Comp. |
| 103 | Cyclohexanone | Carbonyl | a-6 | Dopant-1 | 155.4 | 3.4 | 105 | 105 | D | Comp. |
| 104 | Isobutyl acetate | Ester | a-6 | Dopant-1 | 116.4 | 12.9 | 105 | 105 | C | Comp. |
| 105 | Propionitrile | | a-6 | Dopant-1 | 97.2 | 39.0 | 110 | 80 | B | Inv. |
| 106 | Acetonitrile | | a-6 | Dopant-1 | 80.0 | 72.8 | 110 | 90 | B | Inv. |
| 107 | Fluorobenzene | | a-6 | Dopant-1 | 84.7 | 62.3 | 110 | 80 | A | Inv. |
| 108 | Acetone | Carbonyl | a-6 | Dopant-1 | 56.2 | 185.0 | 125 | 80 | B | Inv. |
| 109 | Isopropyl acetate | Ester | a-6 | Dopant-1 | 88.7 | 43.2 | 140 | 80 | A | Inv. |
| 110 | n-propyl acetate | Ester | a-6 | Dopant-1 | 101.6 | 24.9 | 150 | 70 | A | Inv. |
| 111 | Methylpropionate | Ester | a-6 | Dopant-1 | 79.9 | 60.0 | 150 | 85 | A | Inv. |
| 112 | Ethyl acetate | Ester | a-6 | Dopant-1 | 76.7 | 74.7 | 130 | 90 | B | Inv. |
| 113 | Methyl acetate | Ester | a-6 | Dopant-1 | 58.0 | 170.0 | 130 | 80 | C | Inv. |

Comp.: Comparative sample,
Inv.: Inventive sample

The results given in Table 1 showed that, when forming a light emission layer with a low molecular weight host-guest type phosphorescent light emission material, the external quantum efficiency and driving voltage of the organic EL element were improved while the elevation in voltage under continuous operation was suppressed by employing a solvent exhibiting a low boiling point and a high vapor pressure for the solvent used for forming a light emission layer.

### Example 2

### <<Preparation of Organic EL Element 201>>

Organic EL element 201 was prepared in the same manner as described for Organic EL elements 101 except that an electron transport layer was provided by spin coating a solution obtained by dissolving compound ET-1 (50 mg) in 10 ml of 2,2,3,3-tetrafluoro propanol at 1500 rpm for 30 seconds (thickness of 20 nm), followed by drying at 120° C. for 30 minutes under a nitrogen atmosphere.

### <<Preparation of Organic EL Elements 202-213>>

Organic EL elements 202-213 were prepared in the same manner as described for Organic EL elements 201 except that a-6, Dopant-1 and the solvent were changed to those listed in Table 2, while the mass ratio of the host compound and the dopant was kept constant (light emission host:light emission dopant=100:19) and the concentration of the solution was appropriately adjusted so as to obtain the same coating thickness when the solution was spin coated at 1500 rpm for 30 seconds, to obtain blue light emission layers.

### <<Evaluation of Organic EL Element>>

For the prepared organic EL elements, evaluation was carried out with respect to an external quantum efficiency, a driving voltage, and an elevation in driving voltage under continuous operation in the same manner as described in Example 1. The external quantum efficiency and driving voltage of each organic EL element were expressed as relative values when those values of Organic EL element 201 were set to 100.

TABLE 2

| Organic | | | Light | Light | Boiling | Saturation vapor | External | | Elevation | |
|---|---|---|---|---|---|---|---|---|---|---|
| EL | | Functional | emission | emission | point | pressure (20° C.) | quantum | Driving | in driving | |
| element | Solvent | group | host | dopant | (° C.) | (mmHg) | efficiency | voltage | voltage | Remarks |
| 201 | Ethylbenzene | | a-6 | Dopant-1 | 136.2 | 7.1 | 100 | 100 | D | Comp. |
| 202 | Toluene | | a-6 | Dopant-1 | 110.6 | 21.8 | 105 | 100 | D | Comp. |
| 203 | Cyclohexanone | Carbonyl | a-6 | Dopant-1 | 155.4 | 3.4 | 105 | 110 | D | Comp. |
| 204 | Isobutyl acetate | Ester | a-6 | Dopant-1 | 116.4 | 12.9 | 105 | 110 | D | Comp. |
| 205 | Propionitrile | | a-6 | Dopant-1 | 97.2 | 39.0 | 110 | 80 | B | Inv. |
| 206 | Acetonitrile | | a-6 | Dopant-1 | 80.0 | 72.8 | 110 | 90 | B | Inv. |
| 207 | Fluorobenzene | | a-6 | Dopant-1 | 84.7 | 62.3 | 110 | 80 | A | Inv. |
| 208 | Acetone | Carbonyl | a-6 | Dopant-1 | 56.2 | 185.0 | 125 | 80 | B | Inv. |
| 209 | Isopropyl acetate | Ester | a-6 | Dopant-1 | 88.7 | 43.2 | 140 | 80 | A | Inv. |
| 210 | n-propyl acetate | Ester | a-6 | Dopant-1 | 101.6 | 24.9 | 160 | 70 | A | Inv. |
| 211 | Methylpropionate | Ester | a-6 | Dopant-1 | 79.9 | 60.0 | 150 | 85 | A | Inv. |
| 212 | Ethyl acetate | Ester | a-6 | Dopant-1 | 76.7 | 74.7 | 130 | 90 | B | Inv. |
| 213 | Methyl acetate | Ester | a-6 | Dopant-1 | 58.0 | 170.0 | 130 | 85 | C | Inv. |

Comp.: Comparative sample,
Inv.: Inventive sample

The results given in Table 2 showed that when forming a light emission layer with a low molecular weight host-guest type phosphorescent light emission material, the external quantum efficiency and driving voltage of the organic EL element were improved while the elevation in voltage under continuous operation was suppressed by employing a solvent exhibiting a low boiling point and a high vapor pressure for the solvent used for forming a light emission layer, even in a case when 4 or more layers were formed via a wet process. By forming all the organic layers via a wet process, a high productivity of an organic EL element can be achieved.

### Embodiment 3

### <<Preparation of Organic EL Elements 301-313>>

Organic EL elements 301-313 were prepared in the same manner as described for Organic EL elements 210 except that light emission host 1-6 in the light emission layer was changed to the host compounds listed in Table 3an electron transport layer was provided by spin coating a solution obtained by dissolving compound ET-1 (50 mg) in 10 ml of 2,2,3,3-tetrafluoro propanol at 1500 rpm for 30 seconds (thickness of 20 nm), followed by drying at 120° C. for 30 minutes under a nitrogen atmosphere.

### <<Evaluation of an Organic EL Device>>

For the prepared organic EL elements, evaluation was carried out with respect to an external quantum efficiency, a driving voltage, and an elevation in driving voltage under continuous operation in the same manner as described in Example 1. The external quantum efficiency and driving voltage of each organic EL element were expressed as relative values when those values of Organic EL element 210 were set to 100.

TABLE 3

| | | | Light | | Light | Boiling | Saturation vapor | External | | Elevation in | |
|---|---|---|---|---|---|---|---|---|---|---|---|
| Organic | | Functional | emission | Molecular | emission | point | pressure (20° C.) | quantum | Driving | driving | |
| EL element | Solvent | group | host | weight | dopant | (° C.) | (mmHg) | efficiency | voltage | voltage | Remarks |
| 210 | n-propyl | Ester | a-6 | 484.6 | Dopant-1 | 101.6 | 24.9 | 100 | 100 | A | Inv. |
| | acetate | | | | | | | | | | |
| 301 | n-propyl | Ester | a-33 | 574.7 | Dopant-1 | 101.6 | 24.9 | 105 | 100 | A | Inv. |
| | acetate | | | | | | | | | | |
| 302 | n-propyl | Ester | a-8 | 740.8 | Dopant-1 | 101.6 | 24.9 | 110 | 100 | A | Inv. |
| | acetate | | | | | | | | | | |
| 303 | n-propyl | Ester | a-37 | 951.2 | Dopant-1 | 101.6 | 24.9 | 100 | 95 | A | Inv. |
| | acetate | | | | | | | | | | |
| 304 | n-propyl | Ester | a-38 | 891.1 | Dopant-1 | 101.6 | 24.9 | 105 | 95 | A | Inv. |
| | acetate | | | | | | | | | | |
| 305 | n-propyl | Ester | a-39 | 847.0 | Dopant-1 | 101.6 | 24.9 | 110 | 105 | A | Inv. |
| | acetate | | | | | | | | | | |
| 306 | n-propyl | Ester | host-2 | 1069.3 | Dopant-1 | 101.6 | 24.9 | 90 | 105 | B | Inv. |
| | acetate | | | | | | | | | | |
| 307 | n-propyl | Ester | a-40 | 1780.1 | Dopant-1 | 101.6 | 24.9 | 95 | 110 | B | Inv. |
| | acetate | | | | | | | | | | |
| 308 | n-propyl | Ester | host-1 | 873.2 | Dopant-1 | 101.6 | 24.9 | 100 | 115 | B | Inv. |
| | acetate | | | | | | | | | | |
| 309 | n-propyl | Ester | a-25 | 692.9 | Dopant-1 | 101.6 | 24.9 | 105 | 95 | A | Inv. |
| | acetate | | | | | | | | | | |
| 310 | n-propyl | Ester | a-26 | 540.7 | Dopant-1 | 101.6 | 24.9 | 105 | 100 | A | Inv. |
| | acetate | | | | | | | | | | |
| 311 | n-propyl | Ester | a-28 | 464.6 | Dopant-1 | 101.6 | 24.9 | 100 | 95 | A | Inv. |
| | acetate | | | | | | | | | | |
| 312 | n-propyl | Ester | a-35 | 648.8 | Dopant-1 | 101.6 | 24.9 | 90 | 110 | A | Inv. |
| | acetate | | | | | | | | | | |
| 313 | n-propyl | Ester | a-36 | 664.9 | Dopant-1 | 101.6 | 24.9 | 90 | 105 | B | Inv. |
| | acetate | | | | | | | | | | |

Inv.: Inventive sample

The results given in Table 3 showed that the external quantum efficiency and driving voltage of the organic EL element were improved while the elevation in driving voltage under continuous operation was suppressed by employing a solvent described in the present invention even in the cases when various light emission hosts were used. It is also clear that the above described effect was somewhat reduced when the molecular weight of the light emission host became larger. Further, it is also clear that the above described effect was somewhat reduced in Organic EL element 308 in which a light emission host which is not represented by Formula (a).

### Example 4

### <<Preparation of Organic EL Element 401>>

Organic EL element 401 was prepared in the same manner as described for Organic EL elements 201 except that a green light emission layer was provided by spin coating a solution obtained by dissolving light emission host a-6 (100 mg) and green light emission dopant Ir-1(10 mg) in 10 ml of ethylbenzene at 1500 rpm for 30 seconds (thickness of around 50 nm), followed by drying at 120° C. for 30 minutes under a nitrogen atmosphere.

### <<Preparation of Organic EL Elements 402-404>>

Organic EL elements 402-404 were prepared in the same manner as described for Organic EL elements 401 except that each green light emission layer was formed by using a solvent listed in Table 4, while the mass ratio of a-6 and Ir-1 was kept constant (light emission host:light emission dopant=100:10) and the concentration of the solution was appropriately adjusted so as to obtain the same coating thickness when the solution was spin coated at 1500 rpm for 30 seconds.

### <<Evaluation of Organic EL Element>>

For the prepared organic EL elements, evaluation was carried out with respect to an external quantum efficiency, a driving voltage, and an elevation in driving voltage under continuous driving in the same manner as described in Example 1. The external quantum efficiency and driving voltage of each organic EL element were expressed as relative values when those values of Organic EL element 401 were set to 100.

TABLE 4

| Organic | | | Light | Light | | Boiling | Saturation vapor | External | | Increase in | |
|---|---|---|---|---|---|---|---|---|---|---|---|
| EL | | Functional | emission | emission | | point | pressure (20° C.) | quantum | Driving | driving | |
| element | Solvent | group | host | dopant | Color | (° C.) | (mmHg) | efficiency | voltage | voltage | Remarks |
| 401 | Ethyl benzene | | a-6 | Ir-1 | Green | 136.2 | 7.1 | 100 | 100 | D | Comp. |
| 402 | Isopropyl acetate | Ester | a-6 | Ir-1 | Green | 88.7 | 43.2 | 130 | 80 | A | Inv. |
| 403 | n-propyl acetate | Ester | a-6 | Ir-1 | Green | 101.6 | 24.9 | 150 | 80 | A | Inv. |
| 404 | Methyl propionate | Ester | a-6 | Ir-1 | Green | 79.9 | 60.0 | 140 | 85 | A | Inv. |

Comp.: Comparative sample,
Inv.: Inventive sample

The results given in Table 4 showed that the external quantum efficiency and driving voltage of the organic EL element were improved while the elevation in driving voltage under continuous operation was suppressed in the same way even when the emission color was changed from blue to green.

### Example 5

### <<Preparation of Organic EL Element 501>>

Organic EL element 501 was prepared in the same manner as described for Organic EL elements 201 except that a red light emission layer was provided by spin coating a solution obtained by dissolving light emission host a-6 (100 mg) and red light emission dopant Ir-4 (10 mg) in 10 ml of ethylbenzene at 1500 rpm for 30 seconds (thickness of around 50 nm), followed by drying at 120° C. for 30 minutes under a nitrogen atmosphere.

### <<Preparation of Organic EL Elements 502-504>>

Organic EL elements 502-504 were prepared in the same manner as described for Organic EL elements 501 except that each red light emission layer was formed by using a solvent listed in Table 5, while the mass ratio of a-6 and Ir-4 was kept constant (light emission host:light emission dopant=100:10) and the concentration of the solution was appropriately adjusted so as to obtain the same coating thickness when the solution was spin coated at 1500 rpm for 30 seconds.

### <<Evaluation of Organic EL Element>>

For the prepared organic EL elements, evaluation was carried out with respect to an external quantum efficiency, a driving voltage, and an elevation in driving voltage under continuous operation in the same manner as described in Example 1. The external quantum efficiency and driving voltage of each organic EL element were expressed as relative values when those values of Organic EL element 501 were set to 100.

TABLE 5

| Organic | | | Light | Light | | Boiling | Saturation vapor | External | | Elevation in | |
|---|---|---|---|---|---|---|---|---|---|---|---|
| EL | | Functional | emission | emission | | point | pressure (20° C.) | quantum | Driving | driving | |
| element | Solvent | group | host | dopant | Color | (° C.) | (mmHg) | efficiency | voltage | voltage | Remarks |
| 501 | Ethyl benzene | | a-6 | Ir-4 | Red | 136.2 | 7.1 | 100 | 100 | D | Comp. |
| 502 | Isopropyl acetate | Ester | a-6 | Ir-4 | Red | 88.7 | 43.2 | 140 | 80 | A | Inv. |
| 503 | n-propyl acetate | Ester | a-6 | Ir-4 | Red | 101.6 | 24.9 | 145 | 70 | A | Inv. |
| 504 | Methyl propionate | Ester | a-6 | Ir-4 | Red | 79.9 | 60.0 | 150 | 85 | A | Inv. |

Comp.: Comparative sample,
Inv.: Inventive sample

The results given in Table 5 showed that the external quantum efficiency and driving voltage of the organic EL element were improved while the elevation in driving voltage under continuous operation was suppressed in the same way even when the emission color was changed from blue to red.

### Example 6

### <<Preparation of Organic EL Element 601>>

Organic EL element 601 was prepared in the same manner as described for Organic EL elements 201 except that a white light emission layer was provided by spin coating a solution obtained by dissolving light emission host a-6 (100 mg), blue light emission dopant Dopant-1 (10 mg), green light emission dopant Ir-1 (0.2 mg) and red light emission dopant Ir-4 (0.2 mg) in 10 ml of ethylbenzene at 1500 rpm for 30 seconds (thickness of around 50 nm), followed by drying at 120° C. for 30 minutes under a nitrogen atmosphere.

### <<Preparation of Organic EL Elements 502-504>>

Organic EL elements 502-504 were prepared in the same manner as described for Organic EL elements 501 except that each white light emission layer was formed by using a solvent listed in Table 6, while the mass ratio of a-6, Dopant-1, Ir-1, and Ir-4 was kept constant (a-6:Dopant-1:Ir-1:Ir-4=100:10:0.2:0.2) and the concentration of the solution was appropriately adjusted so as to obtain the same coating thickness when the solution was spin coated at 1500 rpm for 30 seconds.

### <<Evaluation of Organic EL Element>>

For the prepared organic EL elements, evaluation was carded out with respect to an external quantum efficiency, a driving voltage, and an elevation in driving voltage under continuous operation in the same manner as described in Example 1. The external quantum efficiency and driving voltage of each organic EL element were expressed as relative values when those values of Organic EL element 601 were set to 100.

TABLE 6

| | | | | | | | Saturation | | | | |
|---|---|---|---|---|---|---|---|---|---|---|---|
| | | | | | | | vapor | | | Elevation | |
| Organic | | | Light | | | Boiling | pressure | External | | in | |
| EL | | Functional | emission | Light emission | | point | (20° C.) | quantum | Driving | driving | |
| element | Solvent | group | host | dopant | Color | (° C.) | (mmHg) | efficiency | voltage | voltage | Remarks |
| 601 | Ethyl benzene | | a-6 | Dopant-1, Ir-1, Ir-4 | White | 136.2 | 7.1 | 100 | 100 | D | Comp. |
| 602 | Isopropyl acetate | Ester | a-6 | Dopant-1, Ir-1, Ir-4 | White | 88.7 | 43.2 | 135 | 85 | A | Inv. |
| 603 | n-propyl acetate | Ester | a-6 | Dopant-1, Ir-1, Ir-4 | White | 101.6 | 24.9 | 155 | 70 | A | Inv. |
| 604 | Methyl | Ester | a-6 | Dopant-1, Ir-1, Ir-4 | White | 79.9 | 60.0 | 150 | 80 | A | Inv. |
| | propionate | | | | | | | | | | |

Comp.: Comparative sample

The results given in Table 5 showed that the external quantum efficiency and driving voltage of the organic EL element were improved while the elevation in driving voltage under continuous operation was suppressed in the same way even when the emission color was changed from blue to white.

What is claimed is:

1. An organic electroluminescent element comprising:
an organic laminate comprising at least an light emission layer formed via a wet process, the light emission layer comprising a host material and a guest material; and
a pair of electrodes,
wherein a solvent used for forming the light emission layer has a boiling point of 105° C. or less and a saturation vapor pressure at 20° C. of 20 mmHg or more.

2. The organic electroluminescent element of claim 1, wherein the solvent has a boiling point of 75° C. or more and a saturation vapor pressure at 20° C. of 70 mmHg or less.

3. The organic electroluminescent element of claim 1, wherein
the organic laminate further comprises three or more layers selected from the group consisting of a hole injection layer, a hole transport layer, a hole blocking layer, an electron injection layer, an electron transport layer and an electron blocking layer, and
the three or more layers each are formed via a wet process.

4. The organic electroluminescent element of claim 1, wherein the solvent comprises a carbonyl group.

5. The organic electroluminescent element of claim 1, wherein the solvent comprises an ester group.

6. The organic electroluminescent element of claim 1, wherein the solvent is selected from the group consisting of normal propyl acetate, isopropyl acetate and methyl propionate.

7. The organic electroluminescent element of claim 1, wherein a molecular weight of the host material is 1500 or less.

8. The organic electroluminescent element of claim 1, wherein the host material is represented by following Formula (a): 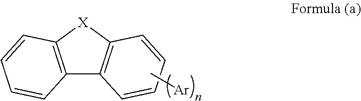
wherein X represents NR′, O, S, CR′R″ or SiR′R″, R′ and R″ each represent a hydrogen atom or a substituent, Ar represents a group of atoms necessary to form an aromatic ring, and n represents an integer of 0-8.

9. The organic electroluminescent element of claim 8, wherein Ar in Formula (a) is selected from the group consisting of a carbazole ring, a carboline ring, a dibenzofuran ring and a benzene ring.

10. The organic electroluminescent element of claim 1, wherein the light emission layer comprises at least three different light emission dopants.

11. A method of manufacturing an organic electroluminescent element comprising,
(I) the steps of
forming an anode on a substrate;
forming an organic laminate on the anode; and
forming a cathode on the organic laminate, or
(II) the steps of
forming a cathode on a substrate;
forming an organic laminate on the cathode; and
forming an anode on the organic laminate,
wherein the step of forming the organic laminate comprises at least a step of forming a light emission layer via a wet process, the light emission layer comprising a host material and a guest material;
wherein a solvent used for forming the light emission layer has a boiling point of 105° C. or less and a saturation vapor pressure at 20° C. of 20 mmHg or more.

12. The method of claim 11, wherein the solvent has a boiling point of 75° C. or more and a saturation vapor pressure at 20° C. of 70 mmHg or less.

13. The method of claim 11, wherein
the organic laminate further comprises three or more layers selected from the group consisting of a hole injection layer, a hole transport layer, a hole blocking layer, an electron injection layer, an electron transport layer and an electron blocking layer, and
the three or more layers each are formed via a wet process.

14. The method of claim 11, wherein the solvent comprises a carbonyl group.

15. The method of claim 11, wherein the solvent comprises an ester group.

16. The method of claim 11, wherein the solvent is selected from the group consisting of normal propyl acetate, isopropyl acetate and methyl propionate.

17. The method of claim 11, wherein a molecular weight of the host material is 1500 or less.

18. The method of claim 11, wherein the host material is represented by following Formula (a): 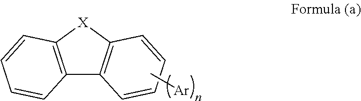
wherein X represents NR′, Q, S, CR′R″ or SiR′R″, R′ and R″ each represent a hydrogen atom or a substituent, Ar represents a group of atoms necessary to form an aromatic ring, and n represents an integer of 0-8.

19. The method of claim 18, wherein Ar in Formula (a) is selected from the group consisting of a carbazole ring, a carboline ring, a dibenzofuran ring and a benzene ring.

20. The method of claim 11, wherein the light emission layer comprises at least three different light emission dopants.
